(19) United States
(12) Patent Application Publication
(10) Pub. No.: US 2024/0292645 A1
(43) Pub. Date: Aug. 29, 2024

(54) LONG LIFE ORGANIC LIGHT EMITTING MATERIALS AND ORGANIC LIGHT EMITTING DIODE

(71) Applicant: LORDIN CO., LTD, Hwaseong-si, Gyeonggi-do (KR)

(72) Inventors: Bubae PARK, Hwaseong-si, Gyeonggi-do (KR); Garam HAN, Osan-si, Gyeonggi-do (KR); Youngjoon KIM, Hwaseongi-si, Gyeonggi-do (KR)

(21) Appl. No.: 18/044,776

(22) PCT Filed: Aug. 5, 2022
(86) PCT No.: PCT/KR2022/011629

§ 371 Date: Mar. 9, 2023

(30) Foreign Application Priority Data
Feb. 15, 2022 (KR) KR10-2022-0019489
Jul. 29, 2022 (KR) KR10-2022-0094692

(51) Int. Cl. H10K 50/12; H10K 50/19; H10K 85/30; H10K 85/60; H10K 101/10; H10K 101/20; H10K 101/40

(52) U.S. Cl. CPC H10K 50/12; H10K 85/342; H10K 85/346; H10K 85/615; H10K 85/633; H10K 85/636; H10K 85/653; H10K 85/654; H10K 85/6572; H10K 85/6576; H10K 85/658; H10K 50/19; H10K 2101/10; H10K 2101/20; H10K 2101/40

(57) ABSTRACT

An organic light emitting diode including the first electrode, the second electrode, and the emission layer positioned between the first electrode and the second electrode, wherein the emission layer includes the multifunctional emitting compound designed to satisfy the conditions described in the detailed descriptions are provided.

### TECHNICAL FIELD

The present disclosure relates to long life organic light emitting materials and an organic light emitting diode.

### BACKGROUND AND SUMMARY

OLED (Organic Light Emitting Diode) is a device in which a hole injected from the anode and an electron injected from the cathode combine in the emission layer through the charge transport layer to form an exciton and it emits light, which is first reported in Appl. Phys. Lett 51, 913. by C. W. Tang in 1987. At that time, the emission layer was composed of Alq3 as a single material. In J. Appl. Phys., Vol. 65, 3610 in 1989, Alq3 was doped with DCM as a red emitting compound and Coumarine 540 as a green emitting compound in small amounts to adjust the emission wavelength and increase efficiency.

### DISCLOSURE

### Technical Problem

An object of the present disclosure is to provide an organic light emitting diode capable of minimizing decrease in light brightness even when driven for a long time by improving light emission stability of a light emitting body.

The objectives of the present disclosure are not limited to the above-mentioned objectives, and other unmentioned objectives and advantages of the present disclosure may be understood by the following description, and will be more clearly understood by the embodiments of the present disclosure. In addition, it will be readily apparent that the objectives and advantages of the present disclosure can be realized by means and combinations thereof set forth in the claims.

### Technical Solution

One of more embodiments include an organic light emitting diode comprising a first electrode, a second electrode and an emission layer interposed between the first electrode and the second electrode,
wherein the emission layer includes a multifunctional emitting compound,
the multifunctional emitting compound includes a charge stabilizing moiety, a connection portion and an emitting moiety,
the connection portion is formed in a linking group or in a spiro connection, connecting the charge stabilizing moiety and the emitting moiety,
the charge stabilizing moiety is an aromatic ring having 6 to 50 carbon atoms or a heteroaromatic fused ring having 5 to 50 carbon atoms,
the charge stabilizing moiety includes at least one atom having an unshared electron pair included in a HOMO or a LUMO wave function of the charge stabilizing moiety,
the charge stabilizing moiety has a polarity greater than 0.00 Debye,
a length of a longest axis of the charge stabilizing moiety is 7.5 Å or more,
a HOMO-LUMO gap energy of the charge stabilizing moiety is greater than or equal to a HOMO-LUMO gap energy of the emissive moiety;
a shortest distance between the charge stabilizing moiety and the emitting moiety by the connection portion is within 6 Å,
the emitting moiety is distinguished by a light emitting core that is a minimum conjugated structure in the emitting moiety, and a substituent part that is a remaining part thereof; or the emitting moiety is composed of the light emitting core only,
the light emitting core includes carbon and hydrogen, and further includes at least one element other than carbon and hydrogen, and deuterium and tritium are defined as a same element as hydrogen,
provided that, in the multifunctional emitting compound,
(i) a case where the substituent part is connected to an atom other than a carbon element in the light emitting core, and the substituent part and the light emitting core together are connected to the charge stabilizing moiety in a spiro connection, so that each of the substituent part and the light emitting core connects to a spiro atom; and
(ii) a case where the substituent part is connected to the charge stabilizing moiety in a spiro connection, and the light emitting core is connected to an atom other than a carbon element in the substituent part; are excluded.

### Advantageous Effects

The organic light emitting diode including the multifunctional emitting compound of the present disclosure increases the light emission stability of the device and minimizes the decrease in brightness even when driven for a long time.

In addition to the effects described above, specific effects of the present disclosure will be described together while explaining specific details for carrying out the present disclosure.

### BRIEF DESCRIPTION OF DRAWINGS

FIG. 1 shows the HOMO-LUMO energy levels of a host and a dopant.

FIG. 2 shows the wave function of the charge stabilizing moiety.

FIG. 3 schematically illustrates a process of deriving the multifunctional emitting compound by chemically connecting a charge stabilizing compound selected according to the predetermined conditions and a light emitting compound.

FIG. 4 is a graph showing PL measurement results of Comparative compound and the multifunctional emitting compound.

### DETAILED DESCRIPTION

### Best Mode

Hereinafter, embodiments of the present disclosure will be described in detail in such a manner that the disclosure may be easily carried out by those skilled in the art to which the present disclosure pertains. The present disclosure may exist as different embodiments and should not be construed as being limited to the ones set forth herein.

The organic light emitting diode according to one embodiment of the present disclosure may include a first electrode, a second electrode and an emission layer interposed between the first electrode and the second electrode.

The emission layer includes a multifunctional emitting compound.

The multifunctional emitting compound includes a charge stabilizing moiety, a connection portion and an emitting moiety.

The connection portion is formed in a linking group or in a spiro connection, connecting the charge stabilizing moiety and the emitting moiety.

The charge stabilizing moiety is an aromatic ring having 6 to 50 carbon atoms or a heteroaromatic fused ring having 5 to 50 carbon atoms.

The charge stabilizing moiety includes at least one atom having an unshared electron pair included in the HOMO or the LUMO wave function of the charge stabilizing moiety.

The charge stabilizing moiety has a polarity greater than 0.00 Debye.

The length of the longest axis of the charge stabilizing moiety is 7.5 Å or more.

The HOMO-LUMO gap energy of the charge stabilizing moiety is greater than or equal to the HOMO-LUMO gap energy of the emissive moiety.

The shortest distance between the charge stabilizing moiety and the emitting moiety by the connection portion is within 6 Å.

The emitting moiety is classified by a light emitting core that is the minimum conjugated structure in the emitting moiety, and a substituent part that is a remaining part thereof; or the emitting moiety is composed of the light emitting core only.

The light emitting core includes carbon and hydrogen, and further includes at least one element other than carbon and hydrogen, and deuterium and tritium are defined as a same element as hydrogen.

In the multifunctional emitting compound,
(i) a case where the substituent part is connected to an atom other than a carbon element in the light emitting core, and the substituent part and the light emitting core together are connected to the charge stabilizing moiety in a spiro connection, so that each of the substituent part and the light emitting core connects to a spiro atom; and
(ii) a case where the substituent part is connected to the charge stabilizing moiety in a spiro connection, and the light emitting core is connected to an atom other than a carbon element in the substituent part; are excluded.

The organic light emitting diode realizes an organic light emitting diode that minimizes decrease in brightness even when driven for a long time by increasing light emitting stability of the device by using the multifunctional emitting compound designed to meet the conditions described above.

Generally, a dopant plays a decisive role in reducing brightness according to operating time of an organic light emitting diode, in addition to the emission wavelength and efficiency of the organic light emitting diode. The multifunctional emitting compound is designed and developed to exhibit stable brightness even when the device is driven for a long time by improving a dopant deterioration mechanism and an energy transfer process.

The electrons and the holes injected into the emission layer are combined at the host of the emission layer to form excitons, and the process in which the energy is transferred to the dopant is described by the method by light of Equation 1 below (FRET, Förster Resonance Energy transfer) and the method by electrons of Equation 2 below (Dexter Electron Transfer).

FRET (Förster Resonance Energy transfer)

$${k}_{ET} = ( \frac{1}{{r}^{6} {τ}_{D}} ) ( \frac{2.07 {κ}^{2} {Q}_{D} J}{128 {π}^{5} {N}_{A} {n}^{4}} ) \qquad [ Equation 1 ]$$

Dexter Electron Transfer

$${k}_{ET} ∝ J {exp}^{( - \frac{2 r}{L} )} \qquad [ Equation 2 ]$$

K_{ET}: rate constant
r: distance between an energy donor and an energy acceptor
T_{D}: PL decay time of an energy donor
K: orientation factor
Q_{D}: PL quantum efficiency of an energy donor
N_{A}: Avogadro's number
n: refractive index
J: defined as Equation 3 as below.

$$J = \int {f}_{D} ( λ ) {ε}_{A} ( λ ) {λ}^{4} d λ \qquad [ Equation 3 ]$$

f_{D}: emission spectrum of an energy donor
ε_{A}: extinction coefficient according to the wavelength of an energy donor
L: the sum of Van der Waals radii
λ: wavelength

Once the dopant receives energy from the host, it becomes excited. That is, it is in the same state as when one of the two electrons present in the HOMO (Highest Occupied Molecular Orbital) level of the dopant has moved to the LUMO (Lowest Unoccupied Molecular Orbital) level. It takes a few nanoseconds to several milliseconds depending on the spin state of the electrons until the electron in the LUMO level descends to the HOMO level and is stabilized again. Considering that the vibrational motion time of a molecule takes place on the order of several picoseconds, the dopant in the excited state constantly interacts with surrounding molecules before being relaxed by light. A new energy level may be created, a chemical reaction may occur, or a decomposition may occur. These series of processes accelerate the decrease in light emission intensity according to the operating time of the organic light emitting diode.

The HOMO-LUMO gap energy of the dopant is always smaller than the HOMO-LUMO gap energy of the host material, but the positions of energy levels between the two materials are not always constant and may appear in two types in FIG. 1. In FIG. 1, E_{HOMO} represents the HOMO energy level of each material, and E_{LUMO} represents the LUMO energy level of each material.

Type 1 is a case where the HOMO energy level of the dopant is higher than the HOMO energy level of the host, and Type 2 is a case where the LUMO energy level of the dopant is lower than the LUMO energy level of the host. Holes are directly injected into the emission layer through the hole transport layer, and electrons are injected into the emission layer through the electron transport layer from the opposite side. Before holes and electrons are injected from the opposite sides of the emission layer with a thickness of 200 to 500 Å and thus the two charges meet to form excitons, holes are trapped (Type 1) or electrons are trapped (Type 2) in the dopant.

Once the charge is trapped in the dopant, the ionized dopant is very unstable and finds a way to stabilize until the opposite charge arrives. It interacts with other excitons already formed around it, or it causes chemical reactions with the surrounding compounds. Sometimes, it decomposes. This series of processes accelerates the decrease in light emission intensity according to the operating time of the organic light emitting device.

When the multifunctional emitting compound is in an excited state or in an ionized state, the emitting moiety is stabilized by the charge stabilizing moiety at a very close distance, so that the organic light emitting device can maintain stable brightness even when the organic light emitting device has been driven for a long time.

The multifunctional emitting compound may have a structure distinguished by three regions including the first part corresponding to the charge stabilizing moiety, the second part corresponding to the connection portion, and the third part corresponding to the emitting moiety, and may be represented as follows.

[First part]-[Second part]-[Third part]

The multifunctional emitting compound may be designed by selecting the charge stabilizing compound for inducing the first part and the light emitting compound for inducing the third part to satisfy the predetermined conditions as described above, and forming the connection portion corresponding to the second part to connect those.

The first role of the charge stabilizing moiety, which is the first part, is to stabilize the emitting moiety that is ionized when charges are trapped in the emitting moiety, or excited.

The second role of the charge stabilizing moiety, which is the first part, is to spatially protect a certain region of the emitting moiety to reduce the probability that the excited or the ionized emitting moiety interacts with other molecules in the vicinity.

The third role of the charge stabilizing moiety, which is the first part, is to spatially protect a certain region of the emitting moiety to reduce the probability that charges are directly trapped in the emitting moiety.

In order for the charge stabilizing moiety to play these roles, it needs to have a polarity (Dipole Moment). Specifically, the charge stabilizing moiety has a polarity greater than 0 Debye. For example, the polarity of materials such as benzene and a biphenyl group is 0 Debye. For example, polarity can be obtained through calculation using DFT.

In addition, the charge stabilizing moiety has an element possessing an unshared pair of electrons. Examples of such elements may include nitrogen, phosphorus, arsenic, antimony, oxygen, sulfur, Se, fluorine, chlorine, or bromine, etc. An element having an unshared pair of electrons included in the charge stabilization moiety may act as an electron donor or an electron acceptor depending on the bonding type, or may stabilize the emitting moiety by making the charge stabilizing moiety polar. In addition, an element containing an unshared pair of electrons necessarily constitutes the HOMO or the LUMO wave function. That is, it should be included in the wave function representing the electron distribution of the HOMO and the LUMO.

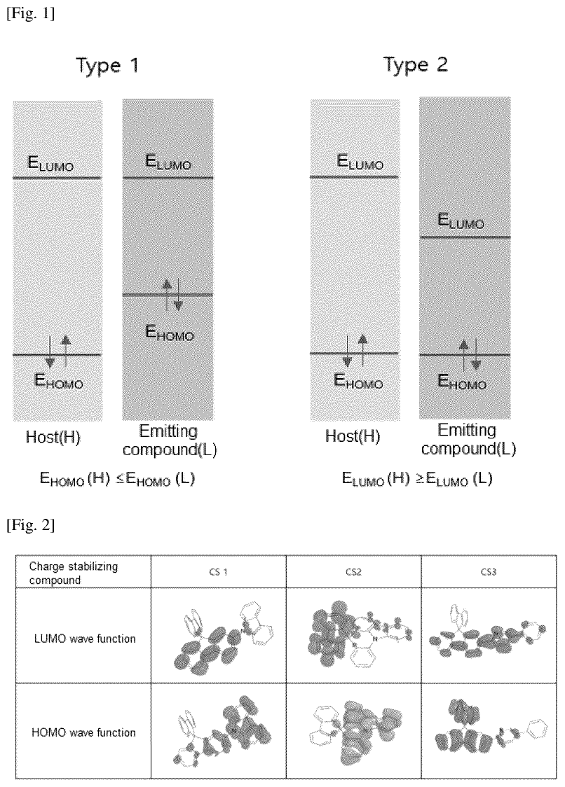

FIG. 2 shows the wave function of the charge stabilizing moiety. In FIG. 2, CS1 and CS2 are the charge stabilizing compounds selected to induce the charge stabilizing moieties. As seen in the HOMO wave functions of CS1 and CS2, it is shown that a high electron density is formed in the nitrogen atom. In this case, when the emitting moiety has a positive charge, the stabilization effect is enhanced. On the other hand, in the case of CS3, it can be confirmed that nitrogen is included in the LUMO wave function, and in this case, a stabilizing effect can be expected when the emitting moiety is negatively charged. Quantum calculations were performed using DFT B3LYP 6-31G* as the basis set.

In one embodiment, the length of the longest axis of the charge stabilizing moiety may be 7.5 Å or more. If the length of the longest axis is too short, it may be difficult to contribute to charge stabilization because of the less spatial interaction with the emitting moiety.

The HOMO-LUMO gap energy of the charge stabilizing moiety should be equal to or greater than the HOMO-LUMO gap energy of the emitting moiety. In this case, the charge stabilizing moiety can stabilize the emitting moiety as described above without receiving energy from the emitting moiety. Meanwhile, when the HOMO-LUMO gap energy of the charge stabilizing moiety is smaller than the energy gap of the emitting moiety, energy may be transferred to the charge stabilizing moiety, resulting in emission of light at the charge stabilizing moiety.

Specifically, the charge stabilizing moiety is:
(i) an aromatic fused ring having 8 to 50 carbon atoms and containing at least one atom having an unshared electron pair included in the HOMO or the LUMO wave function of the charge stabilizing moiety; or an heteroaromatic fused ring having 5 to 50 carbon atoms, or
(ii) an aromatic ring having 6 to 50 carbon atoms and having at least one substituent represented by the structure of Formula 1 or Formula 2 below; or a heteroaromatic fused ring having 5 to 50 carbon atoms and having at least one substituent represented by the structure of Formula 1 or Formula 2 below.

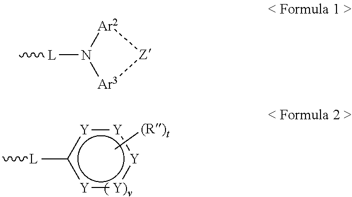

In Formula 1 or Formula 2,

L is a single bond, or a divalent group selected from the group consisting of alkylene having 1 to 20 carbon atoms, alkylsilylene having 1 to 20 carbon atoms, aryl silylene having 1 to 20 carbon atoms, alkylaryl silylene having 1 to 20 carbon atoms, oxygen, sulfur, a divalent group of aryl phosphine having 6 to 20 carbon atoms, a divalent group of aryl phosphine oxide having 6 to 20 carbon atoms, arylene having 6 to 20 carbon atoms, heteroarylene having 5 to 20 carbon atoms and combinations thereof,

Z′ does not exist, or represents a single bond, or is an atom selected from the group consisting of group IIIA, IVA, VA and VIA elements, and when Z′ is an atom, Z′ can have a substituent(s) selected from hydrogen, alkyl having 1 to 20 carbon atoms, an additional substituent substituted or unsubstituted aryl having 6 to 20 carbon atoms, an additional substituent substituted or unsubstituted heteroaryl having 5 to 20 carbon atoms and combinations thereof, in a number according to stoichiometric ratio,

Ar² and Ar³ are, each independently, an alkyl having 1 to 20 carbon atoms, an additional substituent substituted or unsubstituted aryl having 6 to 20 carbon atoms, or an additional substituent substituted or unsubstituted heteroaryl having 5 to 20 carbon atoms,

t is an integer from 0 to 5;

v is 0 or 1

R″ is, each independently, selected from the group consisting of hydrogen, deuterium, alkyl having 1 to 20 carbon atoms, an additional substituent substituted or unsubstituted aryl having 6 to 20 carbon atoms, an additional substituent substituted or unsubstituted heteroaryl having 5 to 20 carbon atoms, alkylamine having 1 to 20 carbon atoms, an additional substituent substituted or unsubstituted arylamine having 6 to 30 carbon atoms, an additional substituent substituted or unsubstituted alkylarylamines having 7 to 30 carbon atoms, halogen, CN, alkoxy having 1 to 20 carbon atoms, an additional substituent substituted or unsubstituted aryloxy having 6 to 30 carbon atoms, an additional substituent substituted or unsubstituted alkylsilyl having 1 to 20 carbon atoms, an additional substituent substituted or unsubstituted arylsilyl having 6 to 30 carbon atoms, an additional substituent substituted or unsubstituted alkylarylsilyl having 7 to 30 carbon atoms, alkylthiol having 1 to 20 carbon atoms, arylthiol having 6 to 20 carbon atoms, aryl phosphine having 1 to 20 carbon atoms, aryl phosphine oxide having 1 to 20 carbon atoms and combinations thereof, and at least two R″ can be linked to each other to form a ring,

the additional substituent is selected from the group consisting of alkyl having 1 to 20 carbon atoms, aryl having 6 to 20 carbon atoms, heteroaryl having 5 to 20 carbon atoms, alkylamine having 2 to 20 carbon atoms, alkylarylamine having 7 to 20 carbon atoms, alkylsilyl having 1 to 20 carbon atoms, arylsilyl having 6 to 20 carbon atoms, alkylarylsilyl having 7 to 30 carbon atoms, alkylthiol having 1 to 20 carbon atoms, arylthiol having 6 to 20 carbon atoms and combinations thereof,

Y is, each independently, nitrogen, oxygen, sulfur or carbon;

[symbol] -0 indicates a connection site,

provided that L or R″ in Formula 2 includes at least one atom having an unshared electron pair included in the HOMO or the LUMO wave function of the charge stabilizing moiety, or at least one of Y is nitrogen, oxygen or sulfur.

When at least two R″ of Formula 2 are connected to form a ring, such a ring includes a fused ring. In addition, the case where two R″ are connected includes the case where any one of the two R″ being connected is hydrogen, and the other R″ of the two being connected directly connects to Y that is connected to the hydrogen R″, with the hydrogen R″ eliminated.

As used herein, the term “substituted” means that a hydrogen atom bonded to a carbon atom in a compound is substituted with another substituent. The position where substitution occurs means the position where a hydrogen atom is substituted. The position is not limited as long as hydrogen at the position can be substituted with a substituent. When two or more substitutions occur, the two or more substituents may be the same or different.

As used herein, a substituent in the case of being “substituted” may be one selected from the group consisting of, for example, deuterium, an alkyl group having 1 to 20 carbon atoms, an alkoxy group having 1 to 20 carbon atoms, a halogen, a cyano group, a carboxy group, a carbonyl group, an amine group, and an alkylamine group having 1 to 20 carbon atoms, a nitro group, an alkylsilyl group having 1 to 20 carbon atoms, an alkoxysilyl group having 1 to 20 carbon atoms, a cycloalkyl silyl group having 3 to 30 carbon atoms, an arylsilyl group having 6 to 30 carbon atoms, an aryl group having 6 to 30 carbon atoms, an arylamine group having 6 to 30 carbon atoms, a heteroaryl group having 5 to 30 carbon atoms, an aryl phosphine oxide group having 6 to 30 carbon atoms, an aryl phosphinyl group having 6 to 30 carbon atoms, an alkyl phosphine oxide group having 6 to 30 carbon atoms, an alkylsulfonyl group having 6 to 30 carbon atoms and their combinations, but is not limited thereto.

Throughout this specification, alkyl includes cycloalkyl and heterocycloalkyl. For example, alkyl amine includes cycloalkyl amine and heterocycloalkyl amine.

In (i), when the charge stabilizing moiety is an aromatic fused ring, it has an atom having an unshared electron pair included in the HOMO or the LUMO wave function of the charge stabilizing moiety in a ring connecting the aromatic rings. In addition, in (i), when the charge stabilizing moiety is an aromatic heterofused ring, the hetero atom corresponds to an atom having an unshared electron pair included in the HOMO or the LUMO wave function of the charge stabilizing moiety.

In (ii), the substituent represented by the structure of Formula 1 or Formula 2 necessarily includes at least one atom having an unshared electron pair included in the HOMO or the LUMO wave function of the charge stabilizing moiety.

As used herein, unless otherwise stated, a ring includes a fused ring.

In one embodiment, the substituent represented by the structure of Formula 1 or Formula 2 may be represented by any of the structures of Formulae D-1 to D-38 below. That is, the charge stabilizing moiety may include any of the structures of Formulae D-1 to D-38 below.

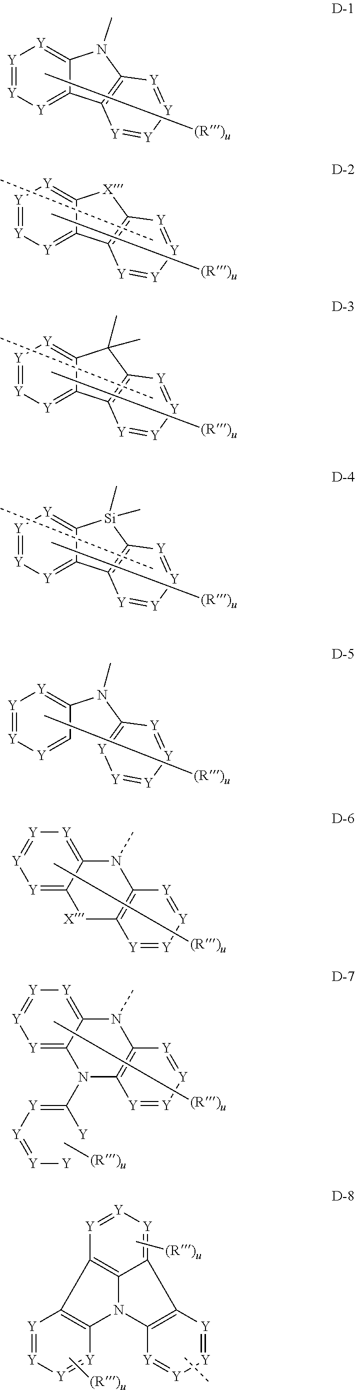

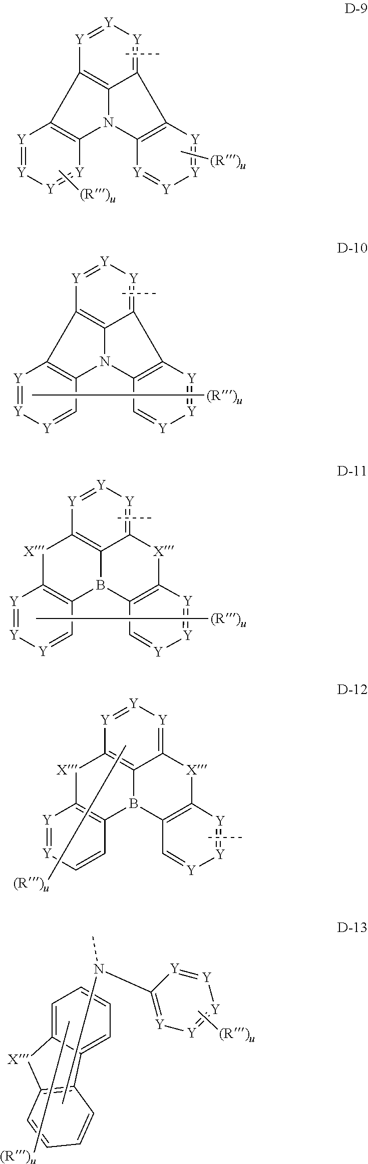

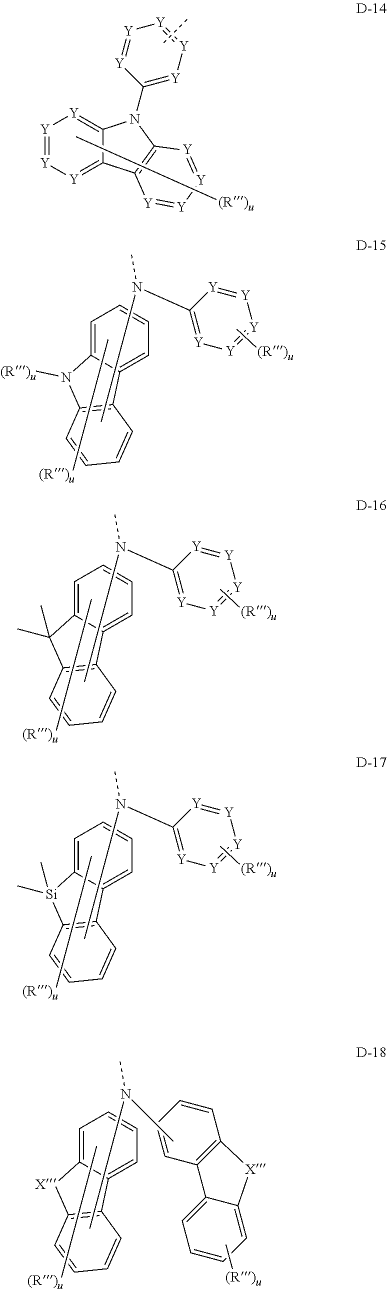

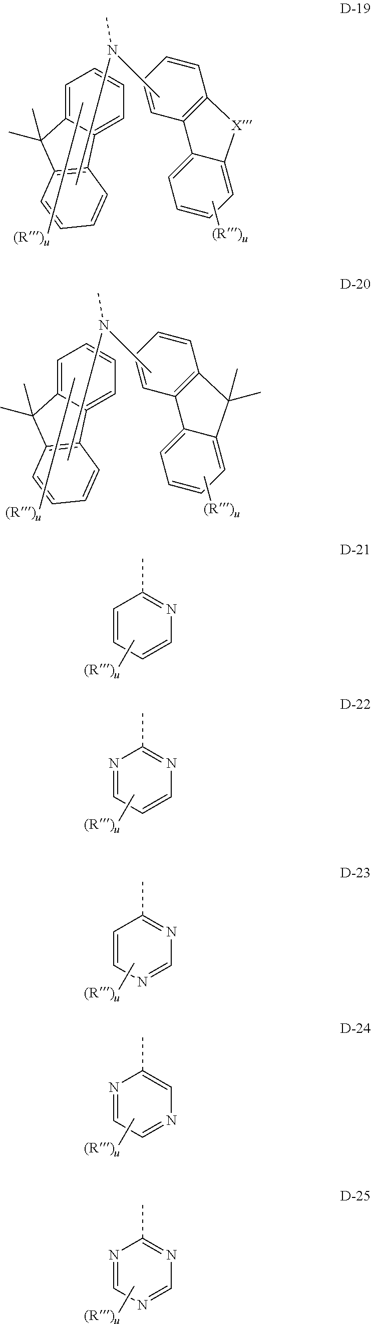

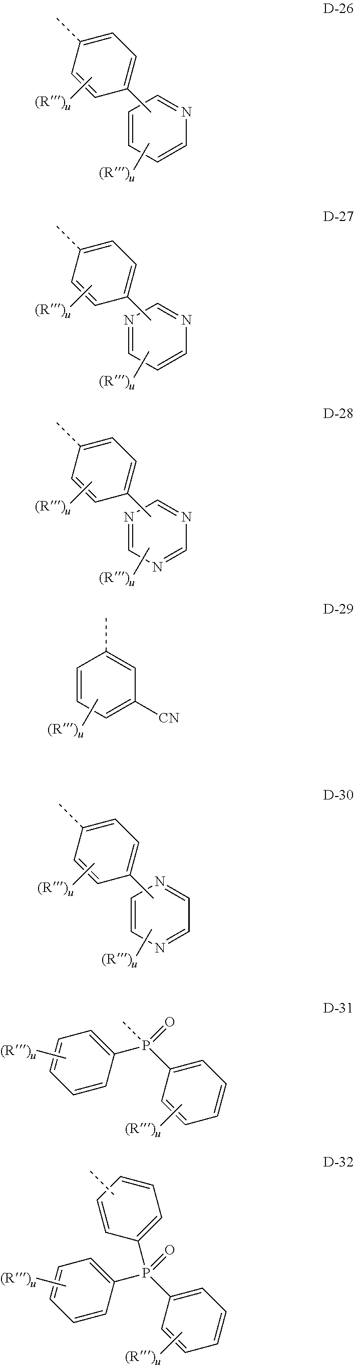

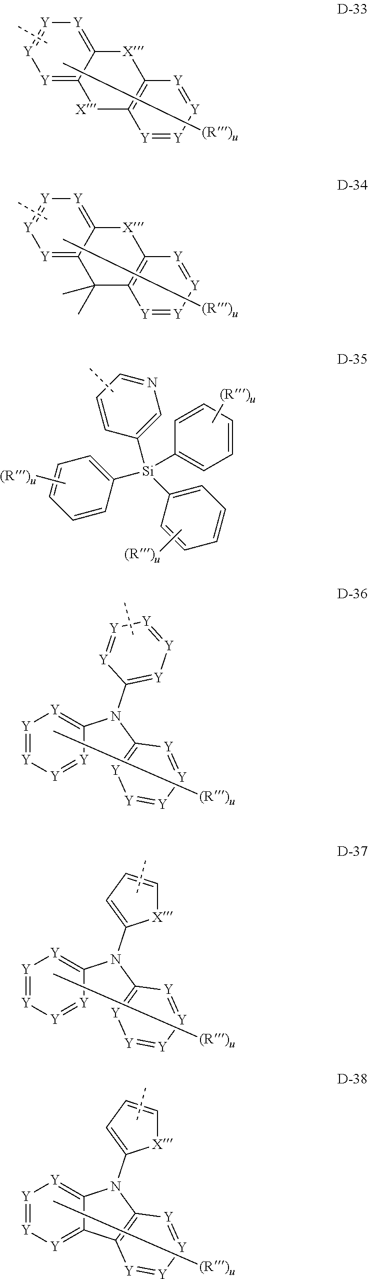

In Formulae D-1 to D-38,

Y is, each independently, carbon or nitrogen,

X″ is, each independently, oxygen, nitrogen, sulfur or selenium,

R′″ is, each independently, selected from hydrogen, deuterium, alkyl having 1 to 20 carbon atoms, aryl having 6 to 20 carbon atoms, heteroaryl having 5 to 20 carbon atoms, alkylamine having 2 to 20 carbon atoms, halogen, CN group, alkylsilyl having 4 to 20 carbon atoms, arylsilyl of 6 to 20 carbon atoms and combinations thereof, u is, each independently, an integer from 0 to 20,

the dotted line represents a connection site,

provided that Formulae D-1 to D-38 include at least one atom having an unshared electron pair included in the HOMO or the LUMO wave function of the charge stabilizing moiety.

The first role of the second part is to ensure that the charge stabilizing moiety and the emitting moiety exist at a certain distance and space. In this way, when the charge stabilizing moiety maintains a spatial position and an angle that do not cause chemical interaction with the emitting moiety, a certain region of the emitting moiety is protected, thereby obtaining an advantage in that the probability of chemical interaction and Coulomb interaction with other dopant materials, host materials and excitons is significantly lowered.

The second role of the second part is to spatially minimize the HOMO or the LUMO wave function overlap between the charge stabilizing moiety and the emitting moiety. This is because when overlapping of the wave functions occurs due to the overlap of the conjugated structure of the charge stabilizing moiety and the emitting moiety, it may cause the problems such as shifting the emission wavelength of the emitting moiety to a longer wavelength or reducing emitting efficiency.

The second part may be formed by connecting the charge stabilizing moiety and the emitting moiety through a spiro connection or may be a linking group.

In one embodiment, the charge stabilizing moiety and the emitting moiety may be connected in a spiro connection having carbon, silicon or Sn as a spiro atom.

In one embodiment, the linking group may be a carbon atom, a silicon atom or a Sn atom. When the linking group is a carbon atom, a silicon atom, or a Sn atom, the linking group may have a substituent(s) selected from hydrogen, an alkyl having 1 to 20 carbon atoms, an aryl having 6 to 20 carbon atoms, a heteroaryl having 5 to 20 carbon atoms and combinations thereof, in the number according to the stoichiometric ratio

The spiro connection or the linking group forming the second part should be formed so as not to significantly affect the electronic state of each of the charge stabilizing moiety (the first part) and the emitting moiety (the third part). As used herein, “not to significantly affect” means that one moiety of the first part or the third part does not change the HOMO energy level, LUMO energy level, or the HOMO-LUMO gap energy of the other moiety by more than 0.2 eV. The criterion for defining the electronic state of each moiety in the multifunctional emitting compound is an independent compound state of a hydrogen-substituted compound where the connection portion (the second part) is separated from each moiety (the first part or the third part), and the separated site is substituted with hydrogen, excluding the connection portion. That is, an independent compound state can be compared where each moiety that has been connected in a linking group or a spiro connection is to be separated and the separated site is substituted with hydrogen. In the case of a linking group, it is an independent compound in which the linking group is replaced with hydrogen. When the spiro connection is separated, the independent compound state can be compared, which is obtained by separating the two bonds connected through the spiro atom to the opposite moiety while being substituted with two hydrogens. At this time, the change in the degree of conjugation of each compound due to the second part (the connection portion) and the change in the electronic state accordingly result from the second part (the connection portion) and are not regarded as being affected by the counter moiety.

The shortest distance between the first part and the third part, by the second part, is within 6 Å. When the distance between the first part and the third part is within the above range, the first and second roles of the second part as described above can be efficiently performed.

The emitting moiety, which is the third part, emits light by receiving exciton energy formed in the charge stabilizing moiety.

The emitting moiety may be derived from an emitting material (referred to herein as a light emitting compound) capable of emitting light by movement of electrons in an organic light emitting diode.

The emitting compound (the light emitting material) may be a compound that can be commonly used as a dopant in an organic light emitting diode. A dopant capable of implementing a desired color may be selected as a light emitting compound according to the purpose, and the emitting moiety may be derived therefrom.

In one embodiment, the emitting moiety may have a conjugated structure having a quantum efficiency of 50% or more in a visible light wavelength range of 400 nm to 700 nm.

In one embodiment, the emitting moiety may have a conjugated structure having a quantum efficiency of 0.5% or more in the 700 nm to 2500 nm near infrared wavelength region.

The core portion of the emitting moiety is characterized in that it is composed of three or more kinds of elements including carbon and hydrogen (deuterium and tritium are defined as the same element as hydrogen).

The emitting moiety may include a light emitting core; and optionally a substituent part. The light emitting core is the minimum conjugated structure in the emitting moiety. The rest except for the light emitting core may be distinguished as a substituent part. The emitting moiety may be formed of only the light emitting core.

When the emitting moiety is divided into molecular conjugated structural units, a portion having the smallest HOMO-LUMO gap energy (Eg) becomes the light emitting core.

In one embodiment, the light emitting core accounts for 50% or more of the total energy of the emission wavelength of the emitting moiety. Here, the energy ratio occupied by the light emitting core is calculated as follows:

$$Energy ratio occupied by the light emitting core = [ Eg ( Emitting moiety ) / Eg ( Light emitting core ) ] \times 100$$

Since the light emitting core includes carbon and hydrogen (deuterium and tritium are defined as the same element as hydrogen) and at least one element other than carbon and hydrogen, the energy difference between a singlet and a triplet can be reduced, which may be advantageous for the systems that use a triplet as light. When the light emitting core is composed of only two elements, carbon and hydrogen, the degree of overlap between the HOMO wave function and the LUMO wave function increases, and thus a large energy difference between a singlet and a triplet occurs. This causes a decrease in emission efficiency in the systems using a triplet as light. Examples include materials such as pyrene, anthracene, fluorene, benzofluroene and benzoanthracene.

In addition, the multifunctional emitting compound excludes:
(i) a case where the substituent part is connected to an atom other than a carbon element in the light emitting core, and the substituent part and the light emitting core together are connected to the charge stabilizing moiety in a spiro connection, so that each of the substituent part and the light emitting core connects to a spiro atom, and
(ii) a case where the substituent part is connected to the charge stabilizing moiety in a spiro connection, and the light emitting core is connected to an atom other than a carbon element in the substituent part.

In the case of (i) above, that is, when the substituent part is connected to the charge stabilizing moiety by a spiro connection together with the light emitting core, the substituent part allows the conjugated structure of the light emitting core to expand greatly, thereby changing the emission properties (the emission wavelength and emission efficiency) of the original emitting moiety itself greatly.

In the case of (ii), that is to say, upon being connected to the charge stabilizing moiety in a spiro connection only through the substituent part, the distance between the charge stabilizing moiety and the light emitting core increases so that the charge stabilizing effect on the emitting moiety is decreased.

Specific examples of the light emitting compound (or light emitting material) may be the following compounds, but are not limited thereto.

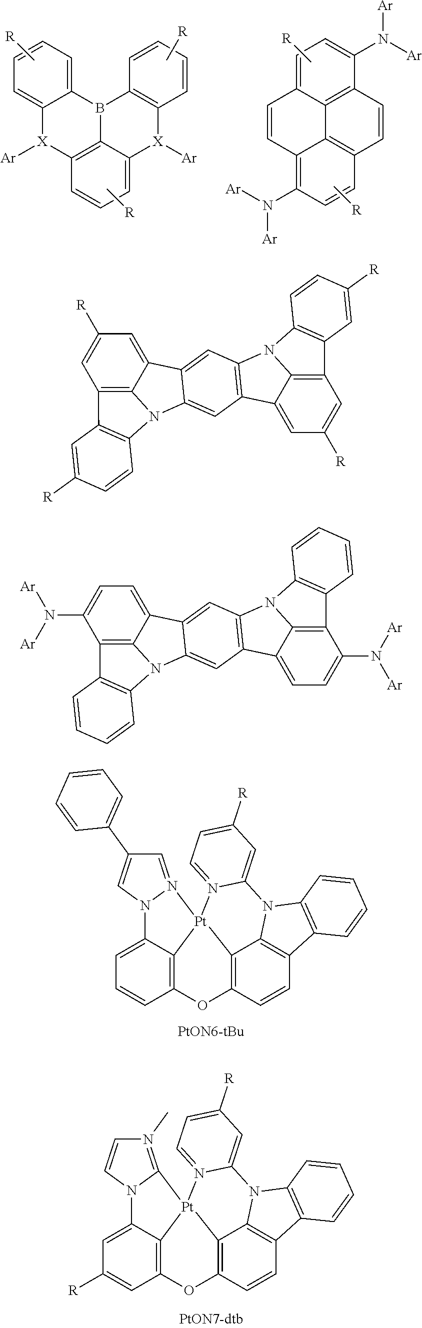

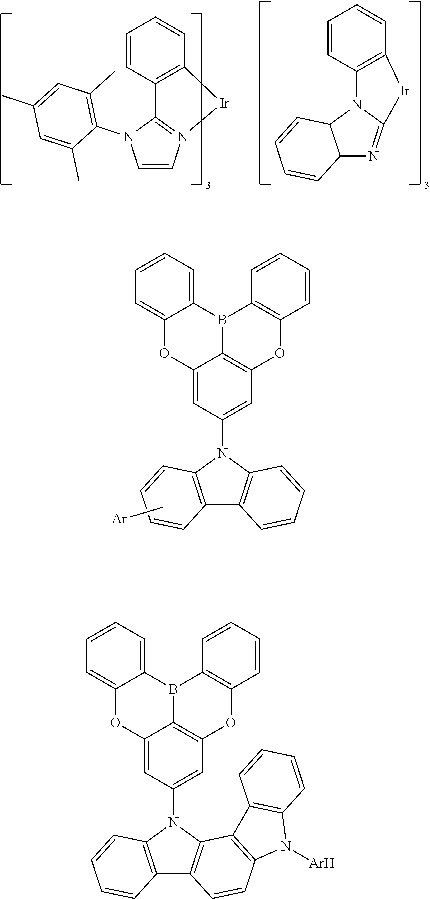

In the above formulae, Ar and R are, respectively, substituted or unsubstituted alkyl having 1 to 20 carbon atoms, substituted or unsubstituted aryl having 6 to 30 carbon atoms, substituted or unsubstituted heteroaryl having 5 to 30 carbon atoms, or substituted, or substituted or unsubstituted arylamine having 6 to 30 carbon atoms, and X is an element of nitrogen, oxygen, sulfur, carbon, silicon, Ge or P.

As described above, the light emitting compound may be a boron compound in which nitrogen, oxygen, sulfur, carbon, silicon, Ge, P, etc. are substituted, a pyrene compound, a compound having a conjugated structure containing nitrogen, and the like, as such in the above structural formulae, but is not limited thereto.

Further, for the light emitting compounds, the materials known as light emitting materials may be used. For example, the light emitting compounds may be the light emitting bodies having the conjugated structures such as anthracene, perylene, tetracene, chrysene, coumarine, pyromethene, etc.

In one embodiment, the light emitting compound and the emitting moiety may have a conjugated structure including boron.

In one embodiment, the light emitting compound and the emitting moiety may contain a metal.

The light emitting mechanism of the emitting moiety may include fluorescence emitting light from a singlet, phosphorescence emitting light from a triplet, and thermally activated delayed fluorescence emitting light when energy is transferred from a triplet to a singlet.

As described above, the aforementioned multifunctional emitting compound may be designed by chemically connecting the charge stabilizing compound and the light emitting compound. The ways of chemically connecting them is as described for the second part above.

When the charge stabilizing compound and the light emitting compound are chemically connected to form the multifunctional emitting compound, the charge stabilizing moiety and the emitting moiety may be derived with a substituent appropriately modified for a chemical bond. In this case, the modified portion for the chemical bond does not significantly change the characteristics of each of the charge stabilizing compound and the light emitting compound, such as emission characteristics, band gap energy, and energy efficiency. For example, the emitting moiety may be formed while a substituent of the light emitting compound is replaced with another substituent for chemical bonding, but the characteristics of the light emission properties, band gap energy, energy efficiency, etc. of the emitting moiety are not significantly affected by the replaced substituent.

As used herein, “not being significantly affected” means not departing from the detailed description of the charge stabilizing moiety and the emitting moiety as described herein. Specifically, what a substituent of the charge stabilizing compound and the light emitting compound are “appropriately” modified upon chemical bonding means that the resulting multifunctional emitting compound conforms to the description herein. That is, by modifying a substituent, it means modifying the band gap of the light emitting compound, increasing quantum efficiency as a common effect of a substituent, etc., but it does not mean causing a drastic change such as reducing the band gap energy, efficiency, etc. by 50% or more.

In one embodiment, the band gap energy of the charge stabilizing moiety may be 1 eV to 4.7 eV, and the band gap energy of the emitting moiety may be 0.5 eV to 3.5 eV. The HOMO energy can be measured by methods such as Cyclic Voltammetry (CV),

Ultraviolet Photoelectron Spectroscopy (UPS), AC2, etc., and the LUMO energy can be measured by UV absorption spectrum or Cyclic Voltammetry (CV).

In one embodiment, the multifunctional emitting compound may be any of the compounds represented by the following structural formulae.

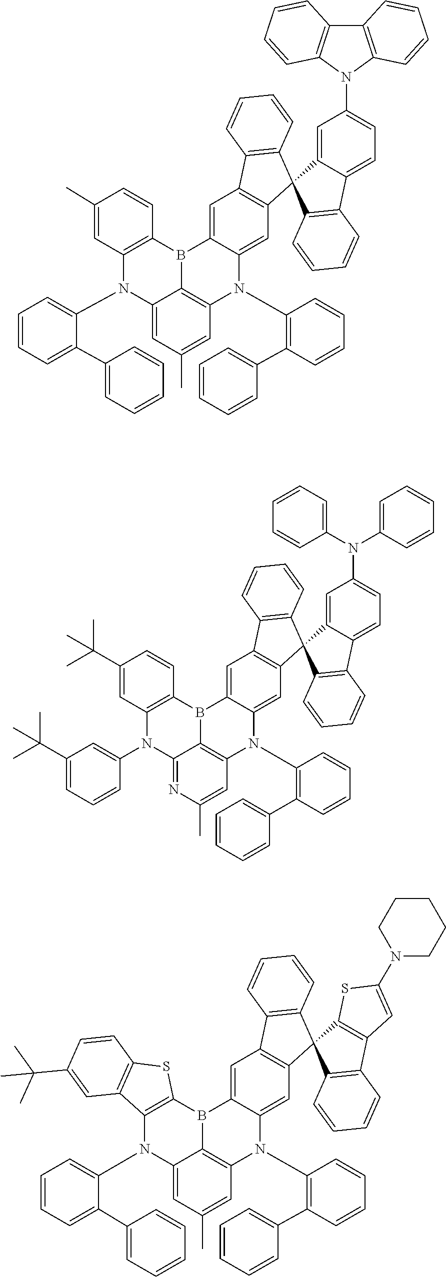 [SMILES: Cc1ccc2c(c1)N(c1ccccc1-c1ccccc1)c1cc(C)cc3c1B2c1cc2c(cc1N3c1ccccc1-c1ccccc1)[C@]1(c3ccccc3-c3ccc(-n4c5ccccc5c5ccccc54)cc31)c1ccccc1-2 ; Cc1cc2c3c(n1)N(c1cccc(C(C)(C)C)c1)c1cc(C(C)(C)C)ccc1B3c1cc3c(cc1N2c1ccccc1-c1ccccc1)[C@]1(c2ccccc2-c2ccc(N(c4ccccc4)c4ccccc4)cc21)c1ccccc1-3 ; Cc1cc2c3c(c1)N(c1ccccc1-c1ccccc1)c1c(sc4ccc(C(C)(C)C)cc14)B3c1cc3c(cc1N2c1ccccc1-c1ccccc1)[C@@]1(c2ccccc2-3)c2ccccc2-c2cc(N3CCCCC3)sc21]

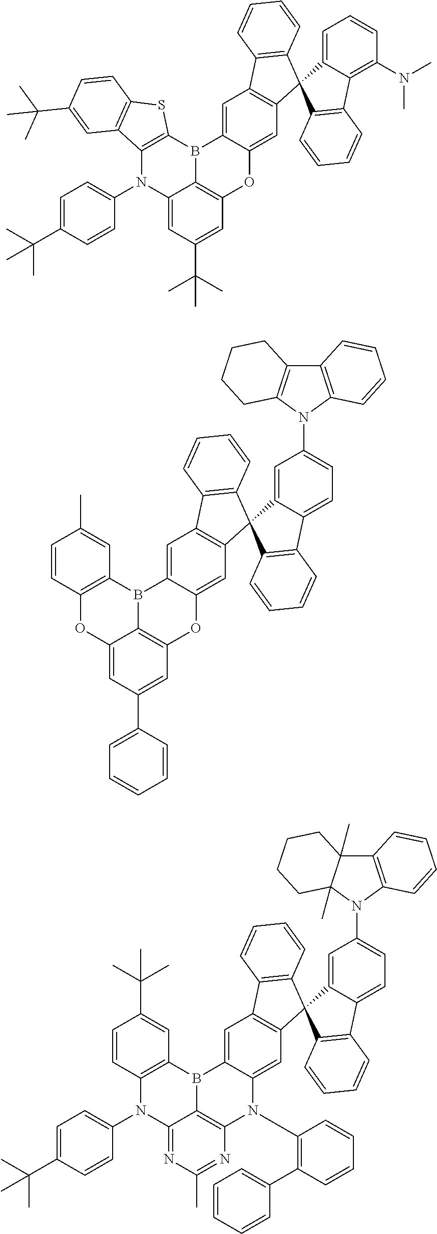

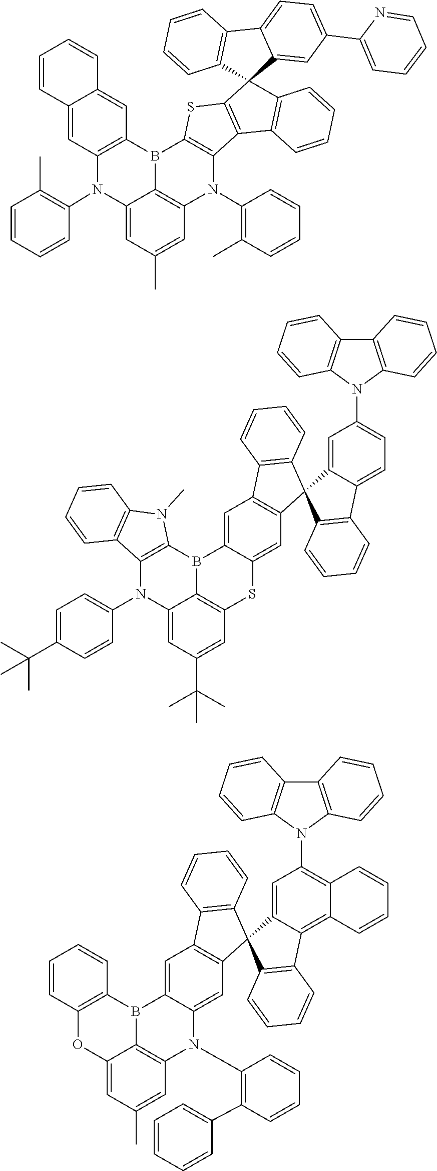 [SMILES: Cc1cc2c3c(c1)N(c1ccccc1C)c1c(sc4c1-c1ccccc1[C@@]41c4ccccc4-c4ccc(-c5ccccn5)cc41)B3c1cc3ccccc3cc1N2c1ccccc1C ; Cn1c2c(c3ccccc31)N(c1ccc(C(C)(C)C)cc1)c1cc(C(C)(C)C)cc3c1B2c1cc2c(cc1S3)[C@]1(c3ccccc3-c3ccc(-n4c5ccccc5c5ccccc54)cc31)c1ccccc1-2 ; Cc1cc2c3c(c1)N(c1ccccc1-c1ccccc1)c1cc4c(cc1B3c1ccccc1O2)-c1ccccc1[C@@]41c2ccccc2-c2c1cc(-n1c3ccccc3c3ccccc31)c1ccccc21]

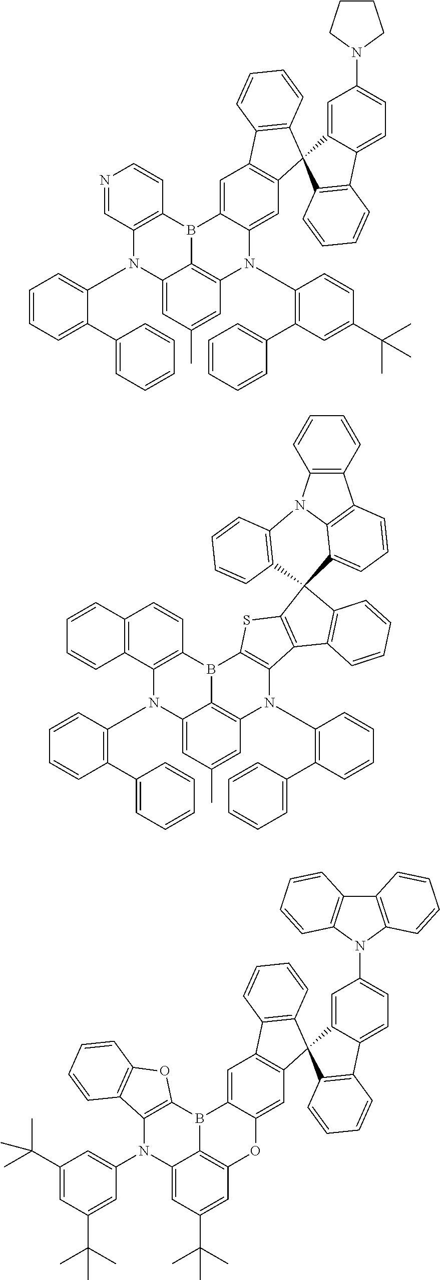

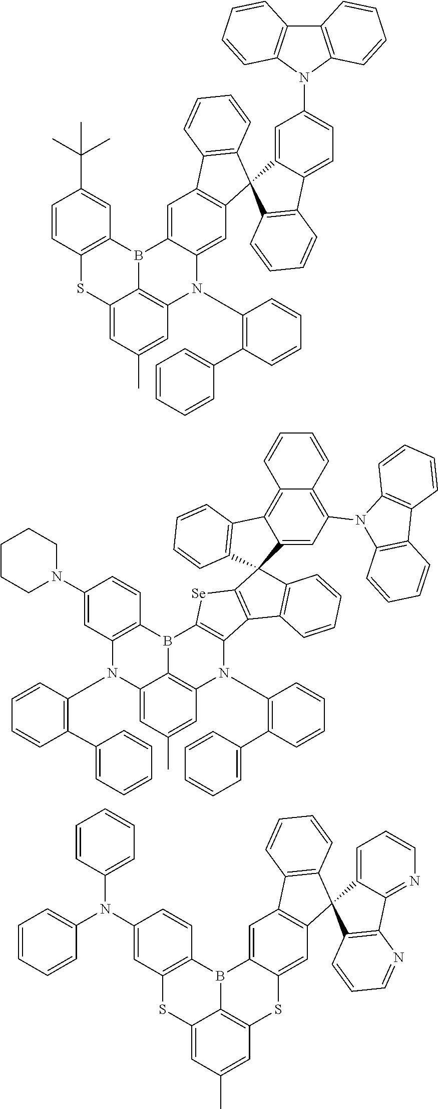

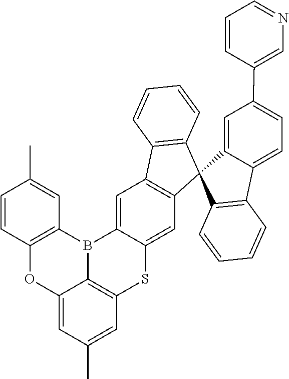 [SMILES: Cc1cc2c3c(c1)Sc1cc4c(cc1B3c1cc(C)ccc1O2)-c1ccccc1[C@@]41c2ccccc2-c2ccc(-c3cccnc3)cc21]

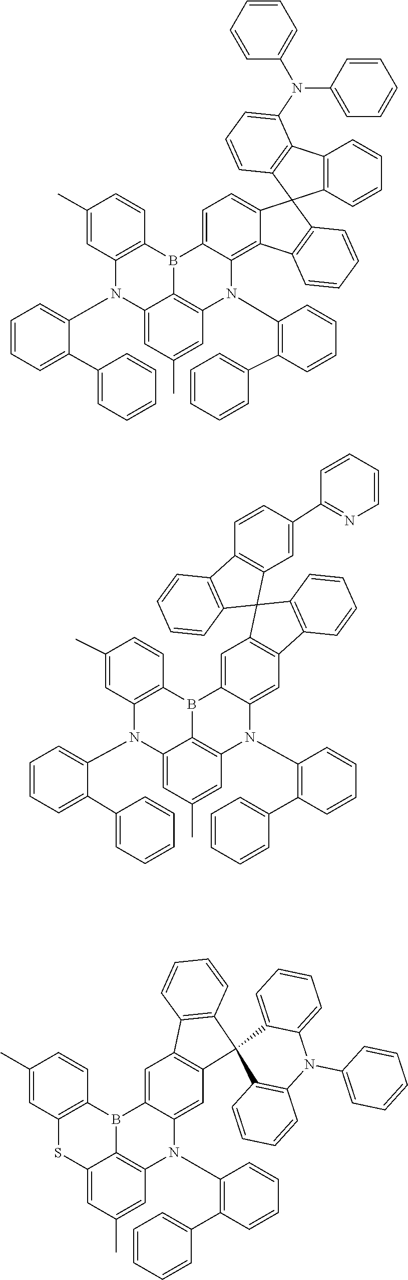

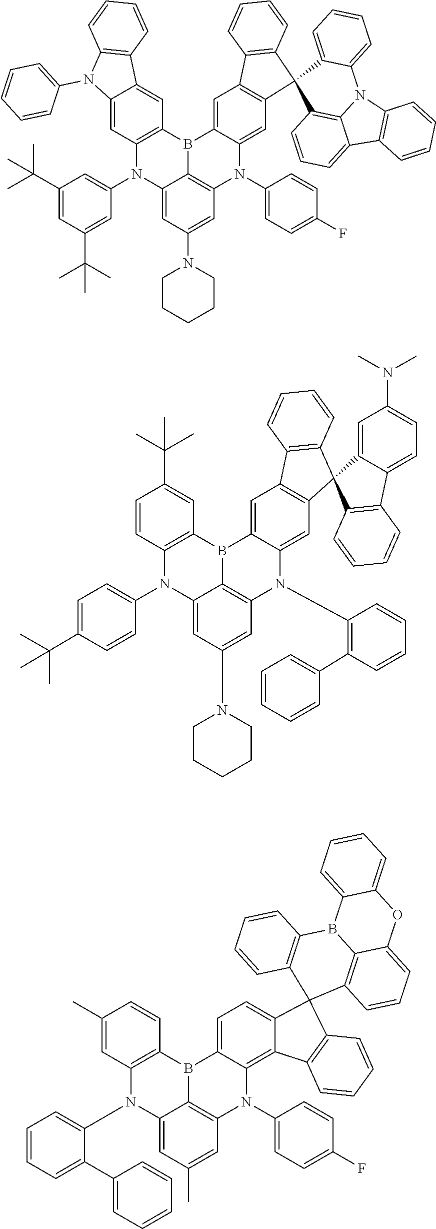 [SMILES: CC(C)(C)c1cc(N2c3cc4c(cc3B3c5cc6c(cc5N(c5ccc(F)cc5)c5cc(N7CCCCC7)cc2c53)[C@]2(c3ccccc3-6)c3ccccc3-n3c5ccccc5c5cccc2c53)c2ccccc2n4-c2ccccc2)cc(C(C)(C)C)c1 ; CN(C)c1ccc2c(c1)[C@@]1(c3ccccc3-2)c2ccccc2-c2cc3c(cc21)N(c1ccccc1-c1ccccc1)c1cc(N2CCCCC2)cc2c1B3c1cc(C(C)(C)C)ccc1N2c1ccc(C(C)(C)C)cc1 ; Cc1ccc2c(c1)N(c1ccccc1-c1ccccc1)c1cc(C)cc3c1B2c1ccc2c(c1N3c1ccc(F)cc1)-c1ccccc1C21c2ccccc2B2c3ccccc3Oc3cccc1c32]

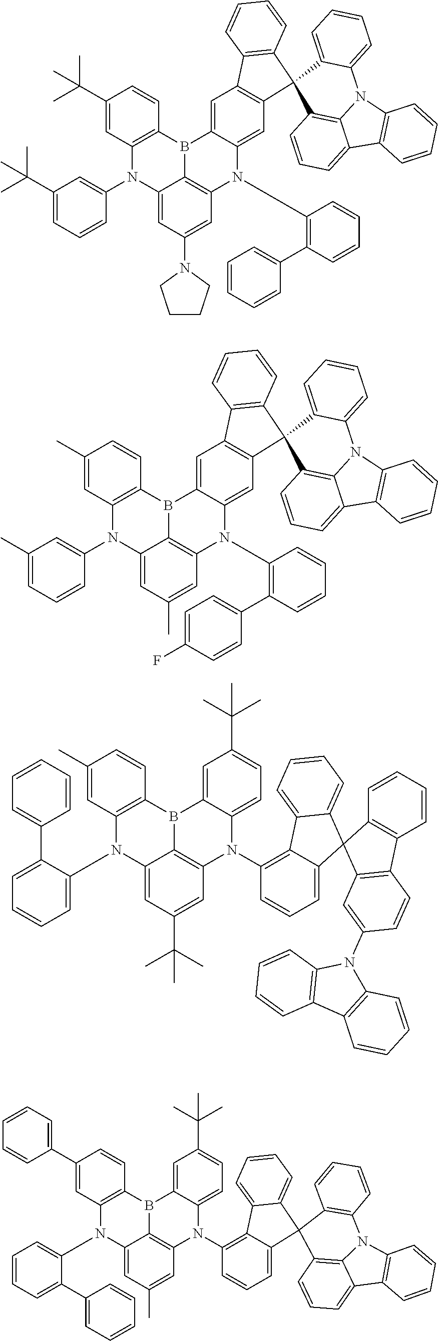

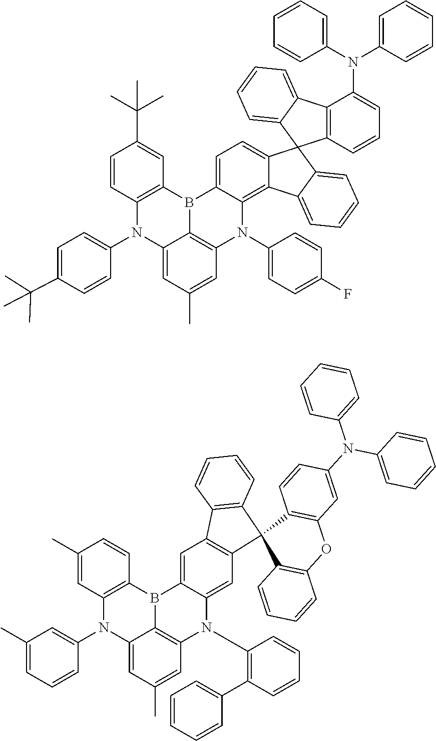 [SMILES: Cc1cc2c3c(c1)N(c1ccc(F)cc1)c1c(ccc4c1-c1ccccc1C41c4ccccc4-c4c(N(c5ccccc5)c5ccccc5)cccc41)B3c1cc(C(C)(C)C)ccc1N2c1ccc(C(C)(C)C)cc1 ; Cc1cccc(N2c3cc(C)ccc3B3c4cc5c(cc4N(c4ccccc4-c4ccccc4)c4cc(C)cc2c43)[C@]2(c3ccccc3Oc3cc(N(c4ccccc4)c4ccccc4)ccc32)c2ccccc2-5)c1]

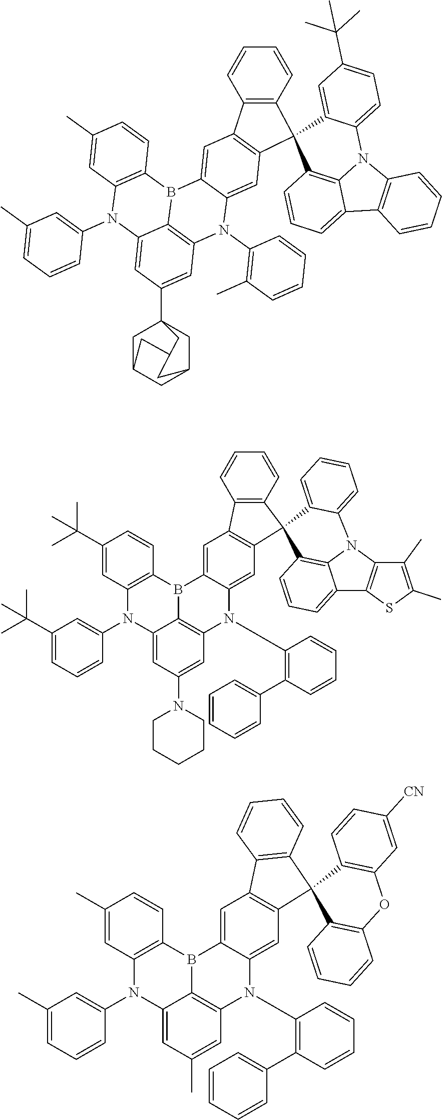

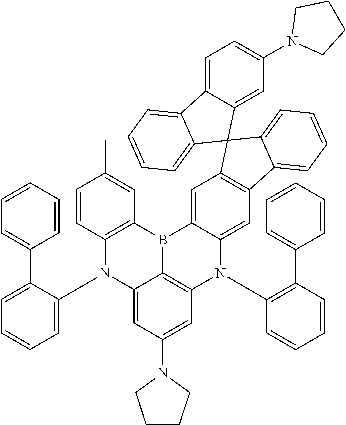 [SMILES: Cc1ccc2c(c1)B1c3cc4c(cc3N(c3ccccc3-c3ccccc3)c3cc(N5CCCC5)cc(c31)N2c1ccccc1-c1ccccc1)-c1ccccc1C41c2ccccc2-c2ccc(N3CCCC3)cc21]

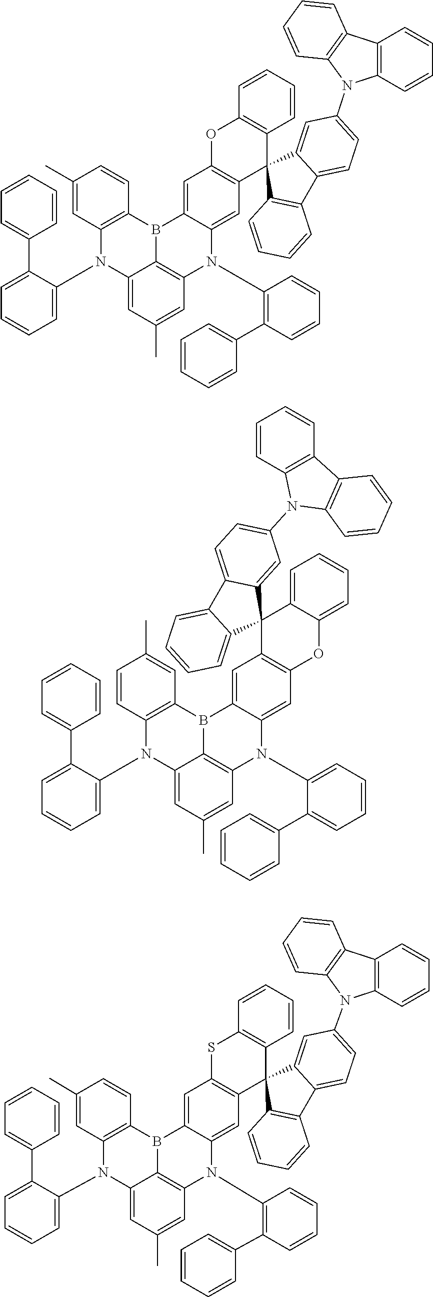 [SMILES: Cc1ccc2c(c1)N(c1ccccc1-c1ccccc1)c1cc(C)cc3c1B2c1cc2c(cc1N3c1ccccc1-c1ccccc1)[C@@]1(c3ccccc3O2)c2ccccc2-c2ccc(-n3c4ccccc4c4ccccc43)cc21 ; Cc1ccc2c(c1)B1c3cc4c(cc3N(c3ccccc3-c3ccccc3)c3cc(C)cc(c31)N2c1ccccc1-c1ccccc1)Oc1ccccc1[C@@]41c2ccccc2-c2ccc(-n3c4ccccc4c4ccccc43)cc21 ; Cc1ccc2c(c1)N(c1ccccc1-c1ccccc1)c1cc(C)cc3c1B2c1cc2c(cc1N3c1ccccc1-c1ccccc1)[C@@]1(c3ccccc3S2)c2ccccc2-c2ccc(-n3c4ccccc4c4ccccc43)cc21]

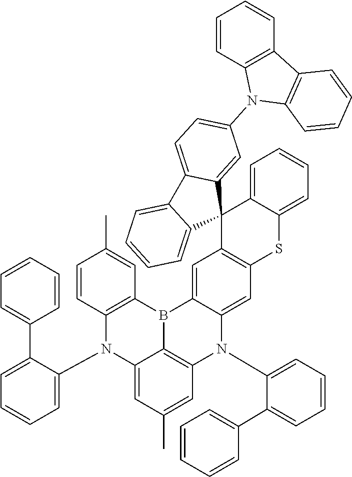 [SMILES: Cc1ccc2c(c1)B1c3cc4c(cc3N(c3ccccc3-c3ccccc3)c3cc(C)cc(c31)N2c1ccccc1-c1ccccc1)Sc1ccccc1[C@@]41c2ccccc2-c2ccc(-n3c4ccccc4c4ccccc43)cc21]

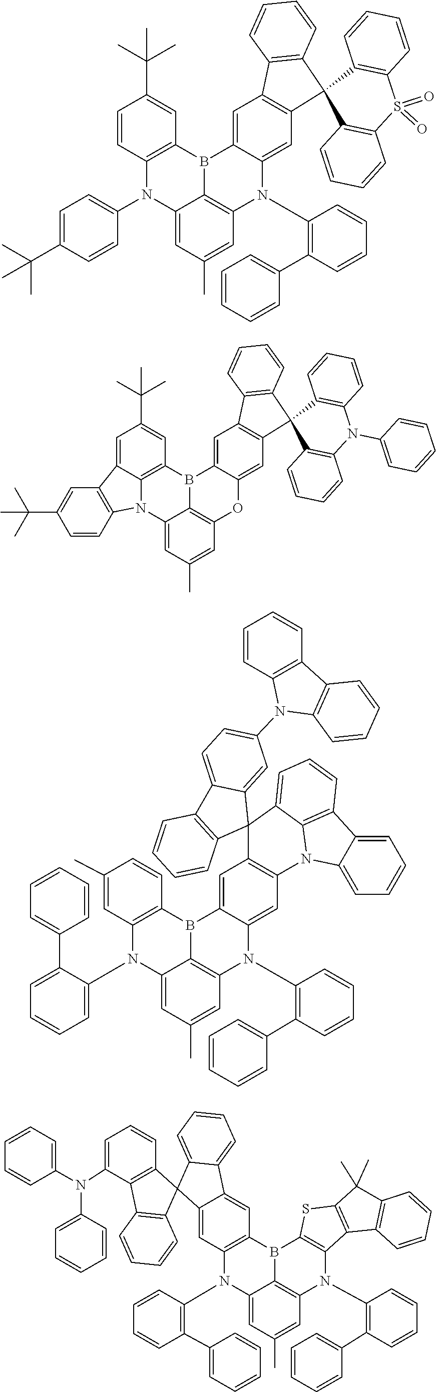

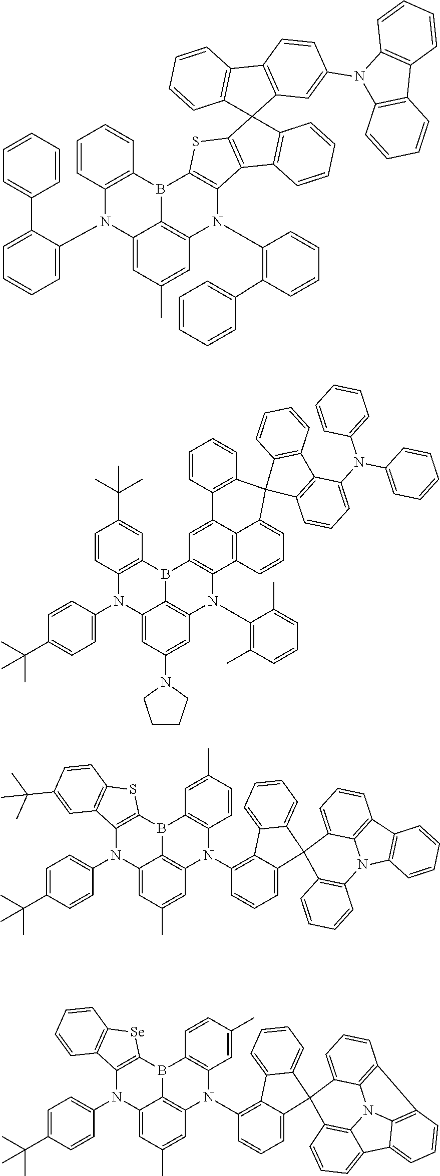

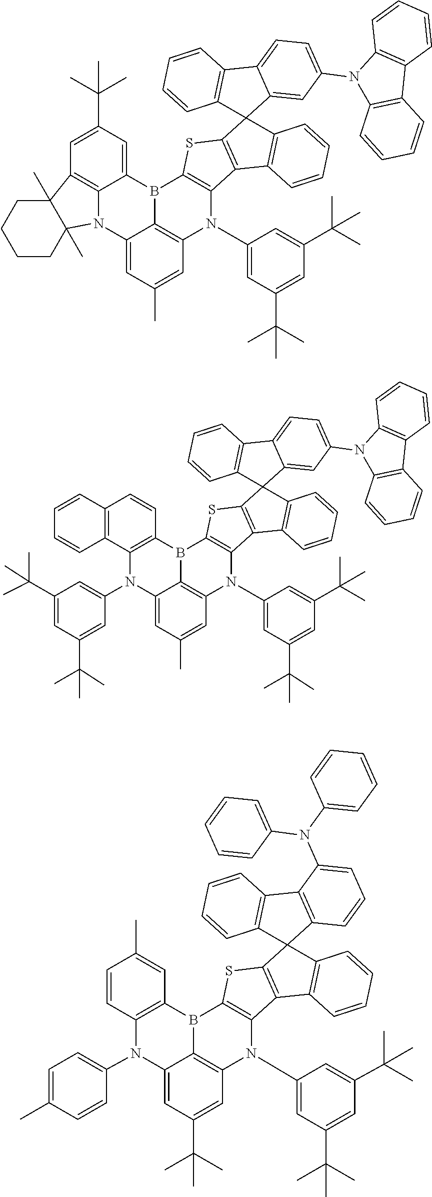 [SMILES: Cc1cc2c3c(c1)N1c4c(cc(C(C)(C)C)cc4C4(C)CCCCC14C)B3c1sc3c(c1N2c1cc(C(C)(C)C)cc(C(C)(C)C)c1)-c1ccccc1C31c2ccccc2-c2ccc(-n3c4ccccc4c4ccccc43)cc21 ; Cc1cc2c3c(c1)N(c1cc(C(C)(C)C)cc(C(C)(C)C)c1)c1c(ccc4ccccc14)B3c1sc3c(c1N2c1cc(C(C)(C)C)cc(C(C)(C)C)c1)-c1ccccc1C31c2ccccc2-c2ccc(-n3c4ccccc4c4ccccc43)cc21 ; Cc1ccc(N2c3ccc(C)cc3B3c4sc5c(c4N(c4cc(C(C)(C)C)cc(C(C)(C)C)c4)c4cc(C(C)(C)C)cc2c43)-c2ccccc2C52c3ccccc3-c3c(N(c4ccccc4)c4ccccc4)cccc32)cc1]

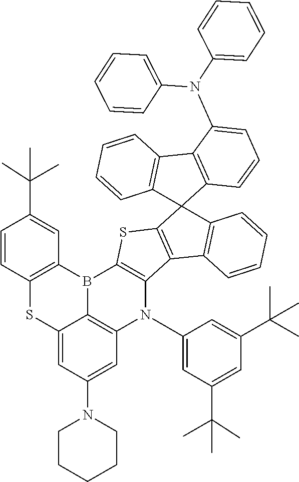 [SMILES: CC(C)(C)c1cc(N2c3cc(N4CCCCC4)cc4c3B(c3cc(C(C)(C)C)ccc3S4)c3sc4c(c32)-c2ccccc2C42c3ccccc3-c3c(N(c4ccccc4)c4ccccc4)cccc32)cc(C(C)(C)C)c1]

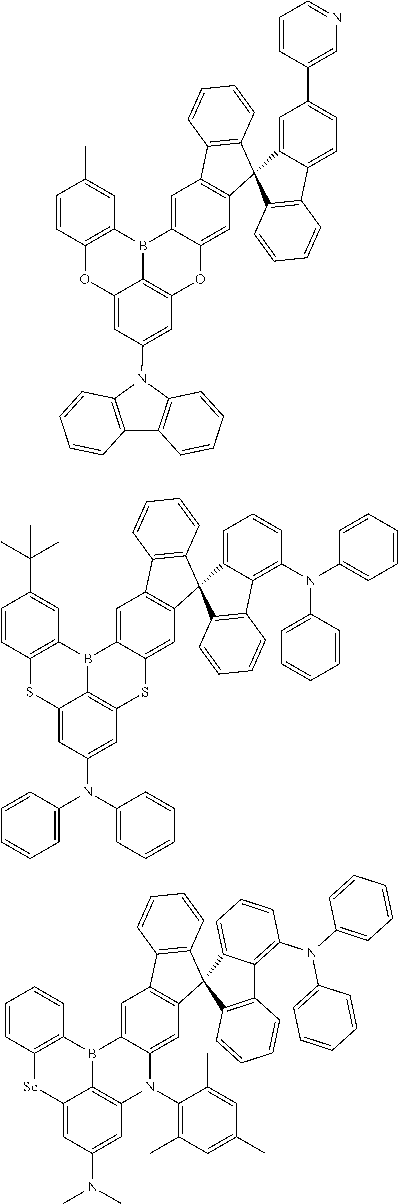

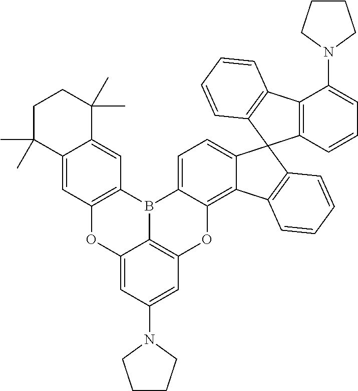 [SMILES: CC1(C)CCC(C)(C)c2cc3c(cc21)Oc1cc(N2CCCC2)cc2c1B3c1ccc3c(c1O2)-c1ccccc1C31c2ccccc2-c2c(N3CCCC3)cccc21]

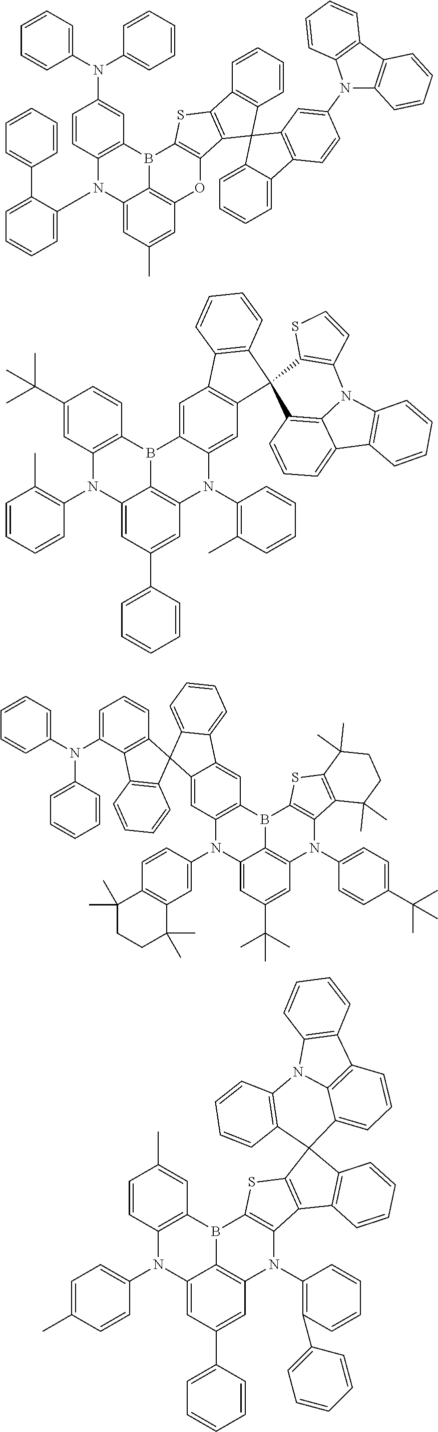

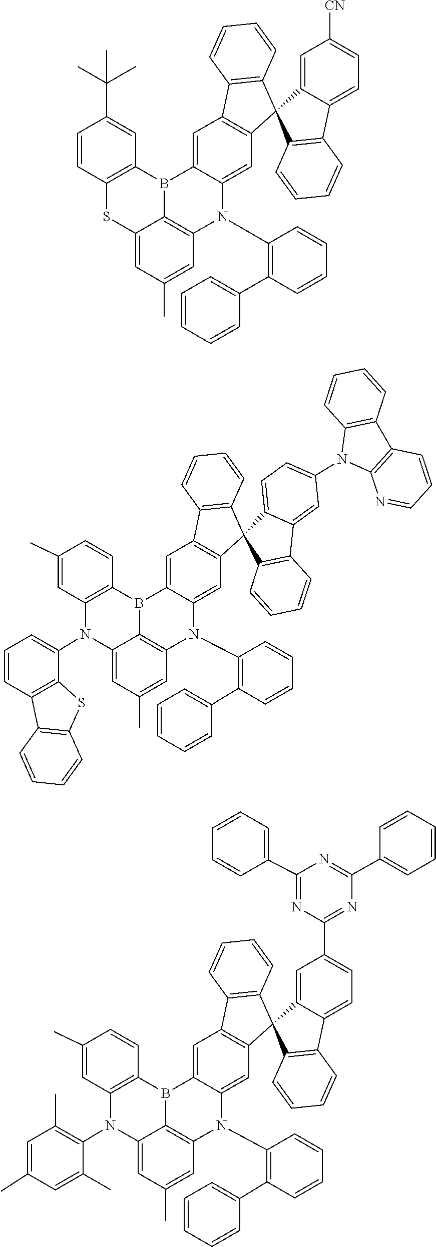 [SMILES: Cc1cc2c3c(c1)N(c1ccccc1-c1ccccc1)c1cc4c(cc1B3c1cc(C(C)(C)C)ccc1S2)-c1ccccc1[C@@]41c2ccccc2-c2ccc(C#N)cc21 ; Cc1ccc2c(c1)N(c1cccc3c1sc1ccccc13)c1cc(C)cc3c1B2c1cc2c(cc1N3c1ccccc1-c1ccccc1)[C@]1(c3ccccc3-c3cc(-n4c5ccccc5c5cccnc54)ccc31)c1ccccc1-2 ; Cc1cc(C)c(N2c3cc(C)ccc3B3c4cc5c(cc4N(c4ccccc4-c4ccccc4)c4cc(C)cc2c43)[C@]2(c3ccccc3-c3ccc(-c4nc(-c6ccccc6)nc(-c6ccccc6)n4)cc32)c2ccccc2-5)c(C)c1]

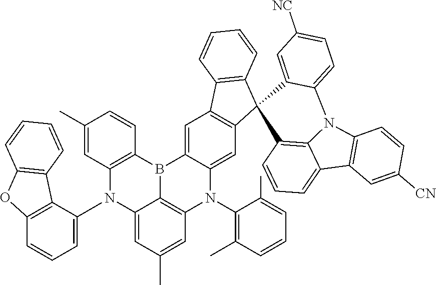 [SMILES: Cc1ccc2c(c1)N(c1cccc3oc4ccccc4c13)c1cc(C)cc3c1B2c1cc2c(cc1N3c1c(C)cccc1C)[C@]1(c3ccccc3-2)c2cc(C#N)ccc2-n2c3ccc(C#N)cc3c3cccc1c32]

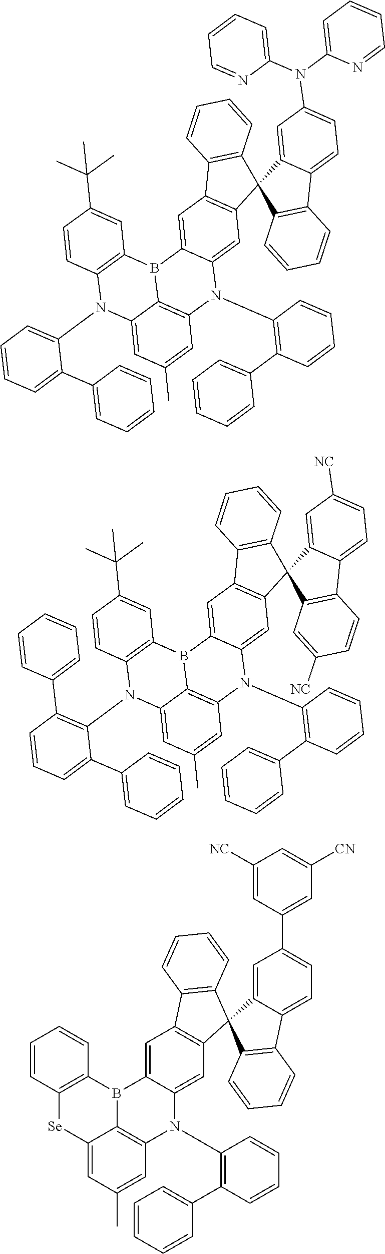

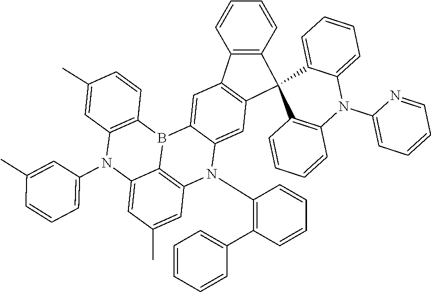

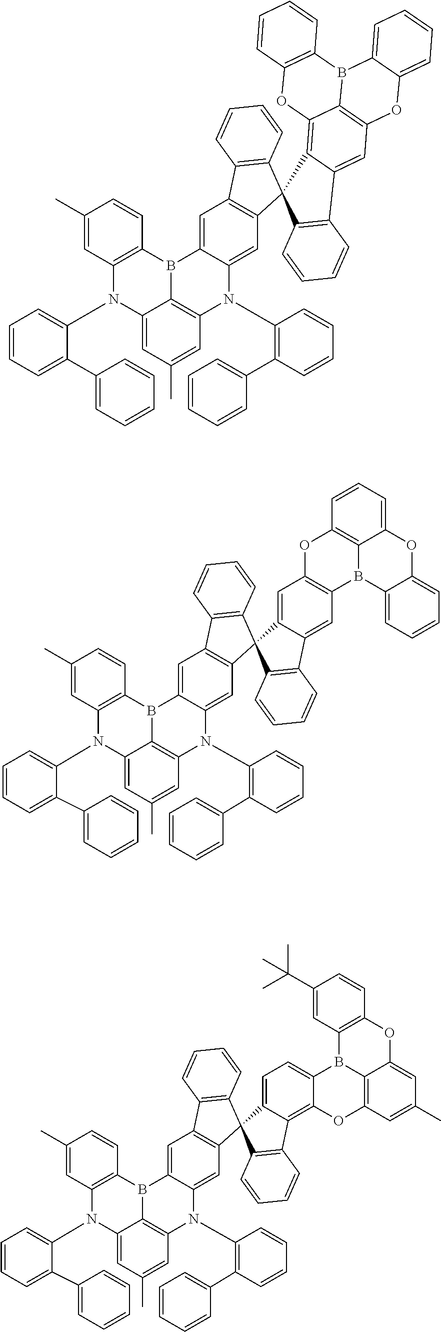 [SMILES: Cc1ccc2c(c1)N(c1ccccc1-c1ccccc1)c1cc(C)cc3c1B2c1cc2c(cc1N3c1ccccc1-c1ccccc1)[C@@]1(c3ccccc3-2)c2ccccc2-c2cc3c4c(c21)Oc1ccccc1B4c1ccccc1O3 ; Cc1ccc2c(c1)N(c1ccccc1-c1ccccc1)c1cc(C)cc3c1B2c1cc2c(cc1N3c1ccccc1-c1ccccc1)[C@]1(c3ccccc3-c3cc4c(cc31)Oc1cccc3c1B4c1ccccc1O3)c1ccccc1-2 ; Cc1cc2c3c(c1)Oc1c(ccc4c1-c1ccccc1[C@@]41c4ccccc4-c4cc5c(cc41)N(c1ccccc1-c1ccccc1)c1cc(C)cc4c1B5c1ccc(C)cc1N4c1ccccc1-c1ccccc1)B3c1cc(C(C)(C)C)ccc1O2]

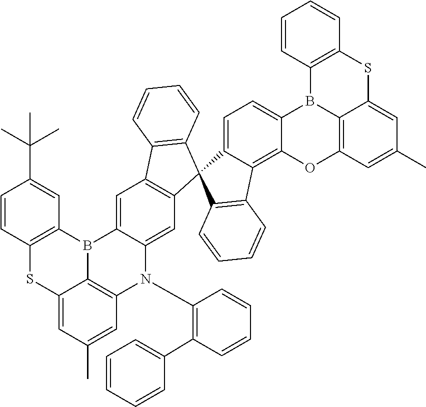 [SMILES: Cc1cc2c3c(c1)Sc1ccccc1B3c1ccc3c(c1O2)-c1ccccc1[C@@]31c2ccccc2-c2cc3c(cc21)N(c1ccccc1-c1ccccc1)c1cc(C)cc2c1B3c1cc(C(C)(C)C)ccc1S2]

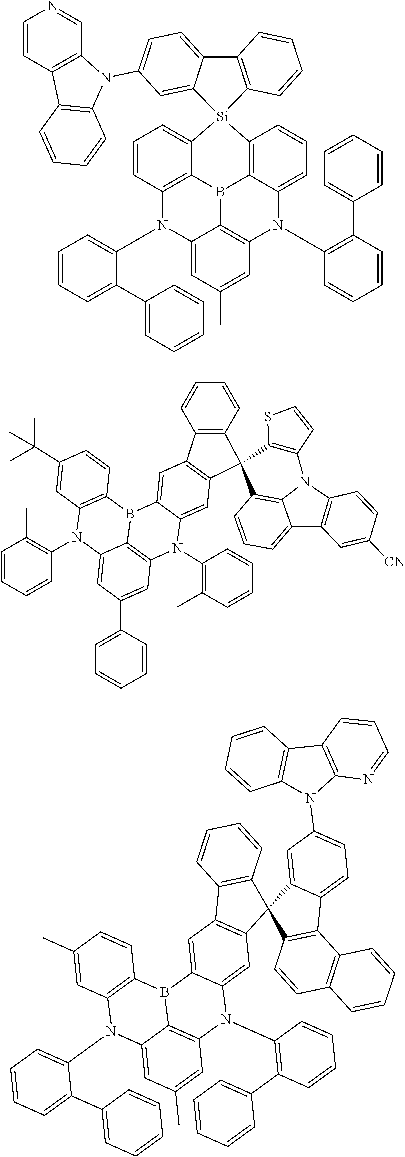

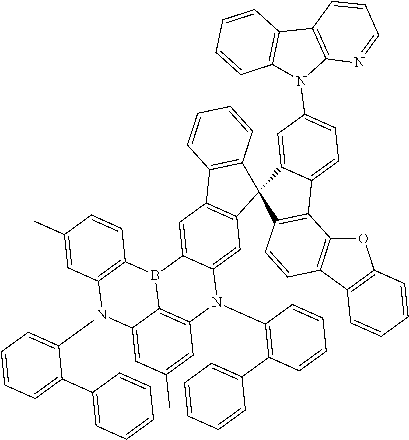 [SMILES: Cc1ccc2c(c1)N(c1ccccc1-c1ccccc1)c1cc(C)cc3c1B2c1cc2c(cc1N3c1ccccc1-c1ccccc1)[C@]1(c3ccccc3-2)c2cc(-n3c4ccccc4c4cccnc43)ccc2-c2c1ccc1c2oc2ccccc21]

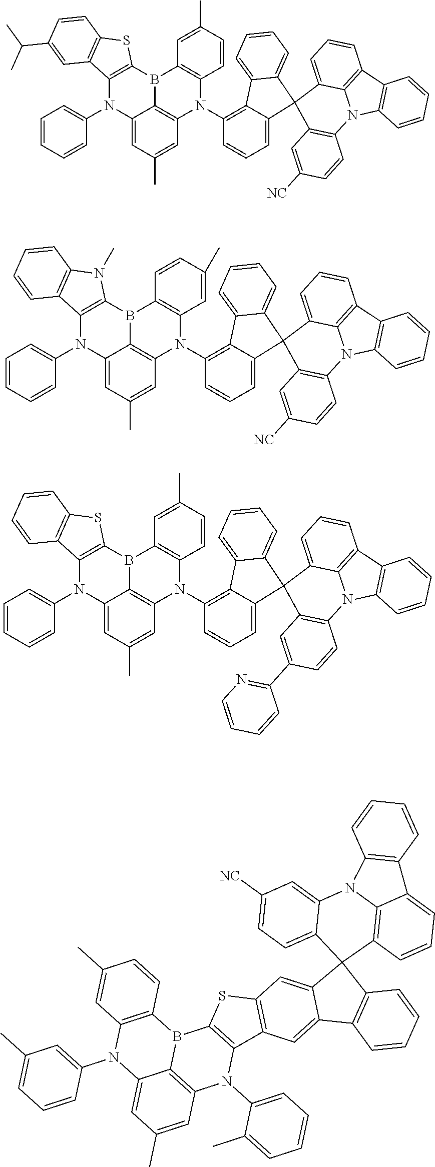 [SMILES: Cc1ccc2c(c1)B1c3sc4ccc(C(C)C)cc4c3N(c3ccccc3)c3cc(C)cc(c31)N2c1cccc2c1-c1ccccc1C21c2cc(C#N)ccc2-n2c3ccccc3c3cccc1c32 ; Cc1ccc2c(c1)N(c1cccc3c1-c1ccccc1C31c3cc(C#N)ccc3-n3c4ccccc4c4cccc1c43)c1cc(C)cc3c1B2c1c(c2ccccc2n1C)N3c1ccccc1 ; Cc1ccc2c(c1)B1c3sc4ccccc4c3N(c3ccccc3)c3cc(C)cc(c31)N2c1cccc2c1-c1ccccc1C21c2cc(-c3ccccn3)ccc2-n2c3ccccc3c3cccc1c32 ; Cc1cccc(N2c3cc(C)ccc3B3c4sc5cc6c(cc5c4N(c4ccccc4C)c4cc(C)cc2c43)-c2ccccc2C62c3ccc(C#N)cc3-n3c4ccccc4c4cccc2c43)c1]

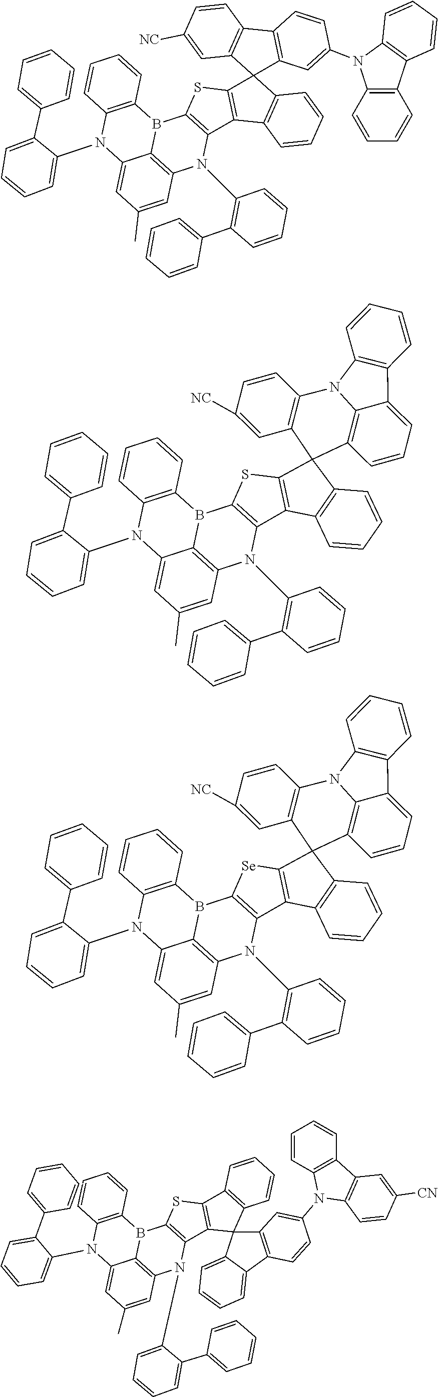

In the multifunctional emitting compound, after selecting the light emitting compound and the charge stabilizing compound to satisfy the above conditions, they are connected in a chemical bond to form a charge stabilizing moiety and an emitting moiety, and the charge stabilizing moiety and the emitting moiety do not cause significant changes in the HOMO energy level, the LUMO energy level and the HOMO-LUMO gap energy of each other due to the chemical bond between them. Thus, the charge stabilizing moiety of the multifunctional emitting compound can stabilize the emitting moiety at a short distance when the emitting moiety exists in an ionic state in which charges are trapped, or in an excited state, without significantly affecting the unique light emission properties of the emitting moiety. In addition, the charge stabilizing moiety protects a certain region of the emitting moiety while maintaining a spatial position and angle that do not cause chemical interaction with the emitting moiety, thereby significantly reducing the probability of chemical interactions and Coulomb interactions with other dopant materials, host materials and excitons.

For the above reasons, the multifunctional emitting compound may increase light emission stability in operating the organic light emitting diode device.

The organic light emitting diode may further include a phosphorescent material in the emission layer to further increase light emitting efficiency of the emission layer.

In one embodiment, the emission layer may further include a phosphorescent material including Pt or Ir.

The compounds represented by the following structural formulae are exemplified as organic metal complexes commonly used as phosphorescent materials. In the formulae below, R may be an alkyl having 1 to 20 carbon atoms, an aryl having 6 to 30 carbon atoms, and the like.

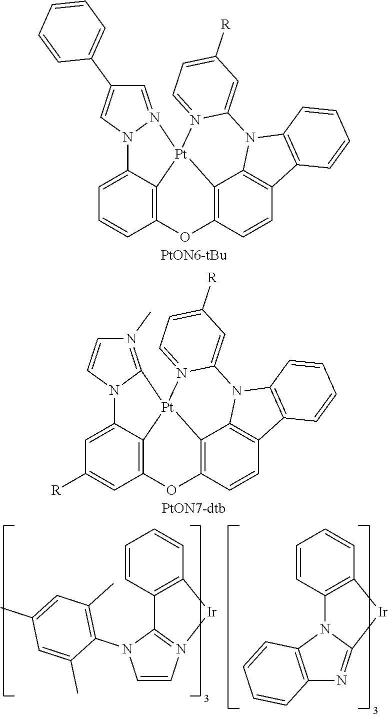

The organic light emitting diode may further include a thermally activated delayed fluorescent material to further increase light emitting efficiency of the emission layer.

In one embodiment, the emission layer may further include a thermally activated delayed fluorescent material having the difference in the energy between a singlet and a triplet of 0.3 eV or more.

The compounds represented by the following structural formulae are shown as examples of commonly used thermally activated delayed fluorescent materials. Ar may be an alkyl having 1 to 20 carbon atoms or an aryl having 6 to 30 carbon atoms.

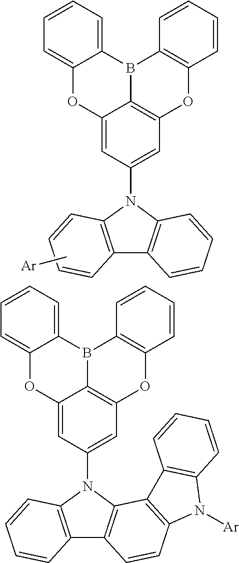

The organic light emitting diode may include, as the organic layer, one selected from the group consisting of a hole injection layer, a hole transport layer, an electron blocking layer, a hole blocking layer, an electron transport layer, an electron injection layer and combinations thereof.

In one embodiment, the organic light emitting diode includes an anode, a hole injection layer (HIL), a hole transport layer (HTL), an emission layer (EML), an electron transport layer (ETL) and a cathode sequentially.

The organic light emitting diode may be a tandem type organic light emitting diode including a plurality of organic light emitting units.

A plurality of the organic light emitting units may be sequentially stacked, and may include a charge generation layer (CGL) between each of the organic light emitting unit. The charge generation layer is positioned between the organic light emitting units, so that charges can be smoothly distributed to the emission layer of each organic light emitting unit.

In the tandem type organic light emitting diode, at least one organic light emitting unit may include an emission layer including the multifunctional emitting compound.

In the tandem type organic light emitting diode, the detailed description of the multifunctional emitting compound is as described above.

Examples and comparative examples of the present disclosure are described below. The following examples are only examples of the present disclosure, but the present disclosure is not limited to the following examples.

### EXAMPLES

In Comparative examples and Examples, Comparative compound 1, Comparative compound 2 and Multifunctional emitting compound 3 as shown below were synthesized.

In Comparative compound 1, L₁ is a t-butyl group and L₂ is an adamantyl group.

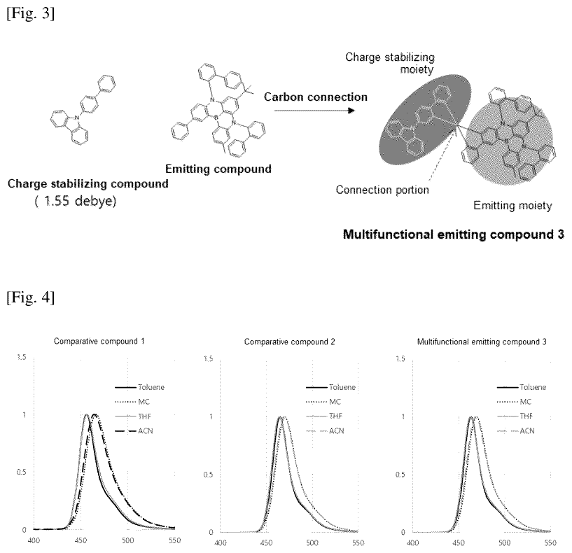

FIG. 3 schematically illustrates the process of deriving the multifunctional emitting compound by chemically connecting the charge stabilizing compound selected according to the conditions and the light emitting compound.

In FIG. 3, the charge stabilizing moiety, the emitting moiety, and the connection portion are shown in the multifunctional emitting compound obtained by chemically bonding the charge stabilizing compound and the light emitting compound.

In Comparative compound 1, the structure excluding the substituents of L₁ and L₂ may correspond to the light emitting compound, but since the substituents of L₁ and L₂ do not satisfy the requirements of the charge stabilization moiety, it is not qualified as the multifunctional emitting compound.

Since the comparative moiety of Comparative compound 2 does not include an atom having an unshared electron pair, Comparative compound 2 is not qualified as the multifunctional emitting compound.

### Synthesis of Comparative Compound 1

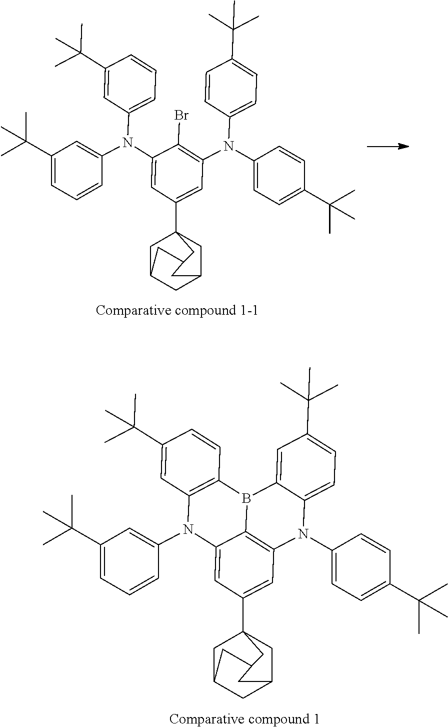

After dissolving 8.48 g (10.0 mmol) of Comparative compound 1-1 in tertiary butylbenzene (32 ml), it was cooled to 0° C. Under a nitrogen atmosphere, 8.0 mL (20.0 mmol) of 2.5M n-butyllithium solution (in hexane) was added and stirred at room temperature for 3 hours.

Then, the reactant was cooled to 0° C. again, and after being added with 1.90 mL (20.0 mmol) of boron tribromide, it was stirred at room temperature for 0.5 hour. The reactants were cooled to 0° C. again, and 3.51 mL (20.0 mmol) of N,N-diisopropylethylamine was added thereto, followed by stirring at 60-70° C. for 2 hours.

The reaction solution was cooled to room temperature, and the organic layer was extracted with ethyl acetate. After drying the solvent of the extracted organic layer with MgSO₄, it was filtered. After concentrating the filtrate under reduced pressure, it was purified using a silica gel column chromatography (DCM/Hexane) method.

Then, recrystallization and purification were performed using a DCM/acetone mixed solvent to obtain 1.05 g of Comparative compound 1 in a yield of 12%.

MS(ACPI) m/z: 779[M+H]

NMR: 8H (500 MHz; CDCl₃; Me₄Si) 8.94 (s, 1H), 8.84 (d, J=10.0, 2.0 Hz, 1H), 7.69 (d, 2H), 7.66-7.56 (m, 2H), 7.51-7.45 (d, 1H), 7.42 (s, 1H), 7.34-7.28 (m, 3H), 7.19 (d, 1H), 7.67 (d, 2H), 6.15 (s, 1H), 6.06 (s, 1H), 1.89 (s, 3H), 1.64 (d, 4H), 1.46 (s, 20H), 1.37 (s, 11H), 1.25 (s, 3H), 1.22 (s, 10H)

### Synthesis of Comparative Compound 2

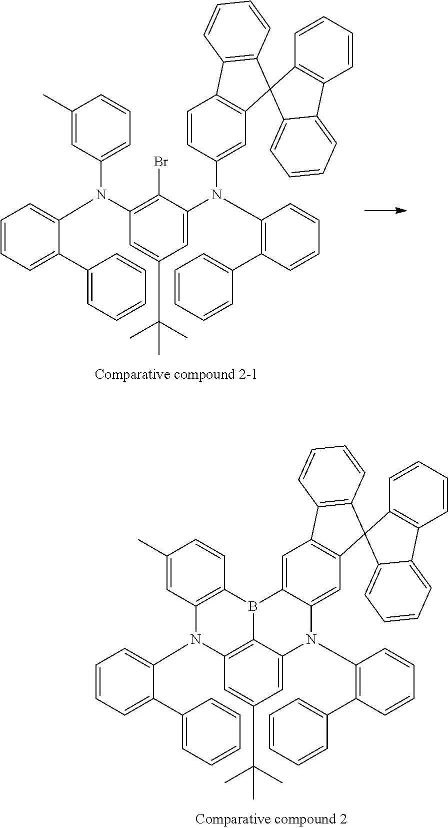 [SMILES: Cc1cccc(N(c2ccccc2-c2ccccc2)c2cc(C(C)(C)C)cc(N(c3ccc4c(c3)C3(c5ccccc5-c5ccccc53)c3ccccc3-4)c3ccccc3-c3ccccc3)c2Br)c1 ; Cc1ccc2c(c1)N(c1ccccc1-c1ccccc1)c1cc(C(C)(C)C)cc3c1B2c1cc2c(cc1N3c1ccccc1-c1ccccc1)C1(c3ccccc3-c3ccccc31)c1ccccc1-2]

After dissolving 9.52 g (10.0 mmol) of the starting material 2-1 in tertiary butylbenzene (32 ml), it was cooled to 0° C. Under a nitrogen atmosphere, 8.0 mL (20.0 mmol) of 2.5M n-butyllithium solution (in hexane) was added and stirred at room temperature for 3 hours.

Then, the reactant was cooled to 0° C. again, and after being added with 1.90 mL (20.0 mmol) of boron tribromide, it was stirred at room temperature for 0.5 hour. The reactants were cooled to 0° C. again, and 3.51 mL (20.0 mmol) of N,N-diisopropylethylamine was added thereto, followed by stirring at 60-70° C. for 2 hours.

The reaction solution was cooled to room temperature, and the organic layer was extracted with ethyl acetate. After drying the solvent of the extracted organic layer with MgSO₄, it was filtered. After concentrating the filtrate under reduced pressure, it was purified using a silica gel column chromatography (DCM/Hexane) method.

Then, recrystallization and purification were performed using a DCM/acetone mixed solvent to obtain 1.05 g of Comparative compound 2 in a yield of 12%.

MS(ACPI) m/z: 881[M+H]

NMR: 8H (400 MHz; CDCl₃; Me₄Si) 9.13(1 H, s), 8.86-8.83 (1H, m), 7.92-7.90 (1H, m), 7.78 (1 H, d, J 8.0), 7.73-7.64 (4H, m), 7.44-7.27 (8H, m), 7.17-6.86 (11H, m), 6.80-6.57 (5H, m), 6.49(1 H, d, J 4.0).6.37(1 H, d, J 8.0), 6.12(2 H, t), 5.89(1 H, d, J 8.0), 2.36(3 H, s), 0.96(9 H, s)

### Synthesis of Multifunctional Emitting Ccompound 3 (Also Referred to as Compound 3)

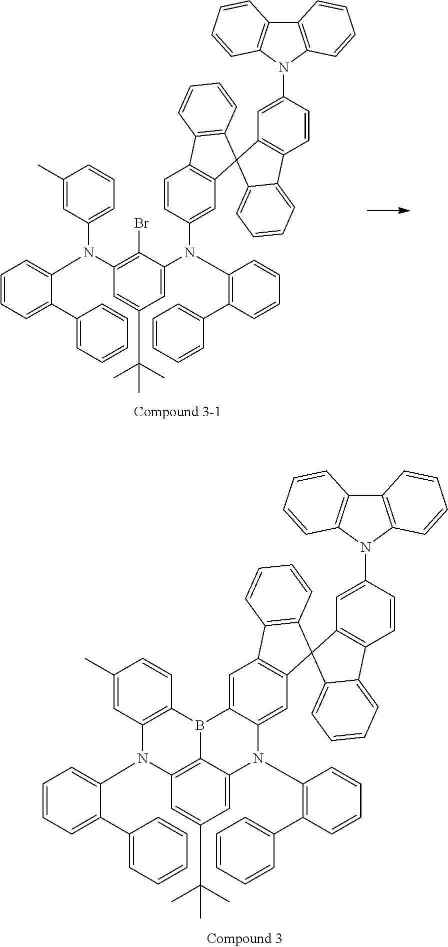 [SMILES: Cc1cccc(N(c2ccccc2-c2ccccc2)c2cc(C(C)(C)C)cc(N(c3ccc4c(c3)C3(c5ccccc5-4)c4ccccc4-c4ccc(-n5c6ccccc6c6ccccc65)cc43)c3ccccc3-c3ccccc3)c2Br)c1 ; Cc1ccc2c(c1)N(c1ccccc1-c1ccccc1)c1cc(C(C)(C)C)cc3c1B2c1cc2c(cc1N3c1ccccc1-c1ccccc1)C1(c3ccccc3-c3ccc(-n4c5ccccc5c5ccccc54)cc31)c1ccccc1-2]

The same method was performed as in Synthesis of Comparative compound 1, except that Compound 3-1 was used instead of Compound 1-1 in the same molar ratio. Thereafter, 1.0 g of Compound 3 was obtained in a 9% yield.

MS(ACPI) m/z: 1046[M+H]

NMR: 8H (400 MHz; CDCl₃; Me₄Si) 9.13(1 H, s), 8.86-8.83 (1H, m), 7.92-7.90 (1H, m), 7.78 (1 H, d, J 8.0), 7.73-7.64 (6H, m), 7.44-7.27 (11H, m), 7.17-6.86 (13H, m), 6.80-6.57 (5H, m), 6.49(1 H, d, J 4.0).6.37(1 H, d, J 8.0), 6.12(2 H, t), 5.89(1 H, d, J 8.0), 2.36(3 H, s), 0.96(9 H, s)

As the measurement results for Compound 3 obtained through calculation (DFT B3LYP 6-31G*), the length of the longest axis of the charge stabilizing moiety was 13.92 Å, and the shortest distance between the charge stabilizing moiety and the emitting moiety was 2.55 Å, and the charge stabilizing moiety had a dipole moment of 1.6 Debye.

### Synthesis of Compound 4

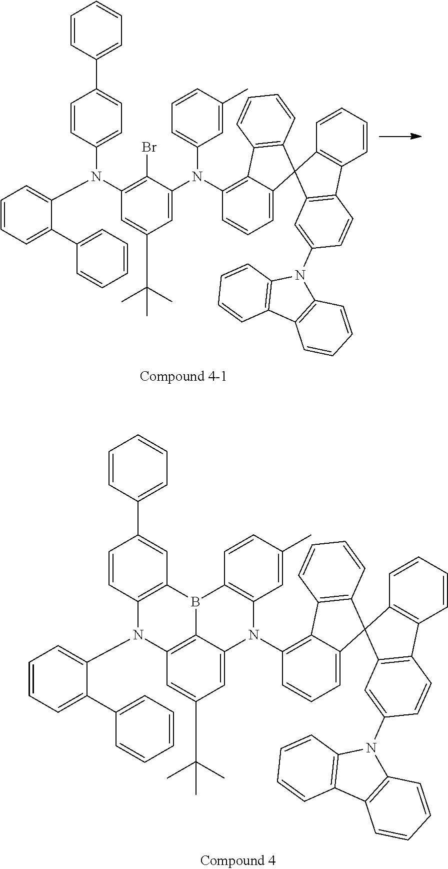 [SMILES: Cc1cccc(N(c2cc(C(C)(C)C)cc(N(c3ccc(-c4ccccc4)cc3)c3ccccc3-c3ccccc3)c2Br)c2cccc3c2-c2ccccc2C32c3ccccc3-c3ccc(-n4c5ccccc5c5ccccc54)cc32)c1 ; Cc1ccc2c(c1)N(c1cccc3c1-c1ccccc1C31c3ccccc3-c3ccc(-n4c5ccccc5c5ccccc54)cc31)c1cc(C(C)(C)C)cc3c1B2c1cc(-c2ccccc2)ccc1N3c1ccccc1-c1ccccc1]

The same method was performed as in Synthesis of Comparative compound 1, except that Compound 4-1 was used instead of Compound 1-1 in the same molar ratio. Thereafter, 0.84 g of Compound 5 was obtained in an 8% yield.

MS(ACPI) m/z: 1046[M+H]

NMR: 8H (500 MHz; CDCl₃; Me₄Si) 8.92-8.82 (2H, m), 8.11-8.04 (3H, m), 7.97-7.95 (1H, dd), 7.80-7.60 (8H, m), 7.53-7.46 (5H, m), 7.38-7.26 (5H, m), 7.25-7.08 (7H, m), 7.03-6.68 (12H, m), 6.18-6.06 (1 H, M) 1.73-1.66 (3 H, d), 1.00 (9 H, s)

As the measurement results for Compound 4 obtained through calculation (DFT B3LYP 6-31G*), the length of the longest axis of the charge stabilizing moiety was 13.92 Å, and the shortest distance between the charge stabilizing moiety and the emitting moiety was 3.10 Å, and the charge stabilizing moiety had a dipole moment of 1.6 Debye.

### Evaluation Example 1: PL Measurements

Comparative compound 1, Comparative compound 2, and Multifunctional emitting compound 3 were dissolved in toluene, methylene chloride (MC), tetrahydrofuran (THF), and acetonitrile, respectively, to a 2 micromolar concentration and excited with a wavelength of 290 nm. The PL (photoluminescence) phenomenon was observed to confirm whether the charge stabilizing moiety can reduce the interaction between the emitting moiety and surrounding molecules. PL was measured by SHIMADZU RF5301PC, SHIMADZU UV 2550.

FIG. 4 and Table 1 below are PL measurement results.

TABLE 1

| | Comparative | | Comparative | | Multifunctional | |
|---|---|---|---|---|---|---|
| | compound 1 | | compound 2 | | emitting compound 3 | |
| | PLₘₐₓ | FWHM | PLₘₐₓ | FWHM | PLₘₐₓ | FWHM |
| Solvent | (nm) | (nm) | (nm) | (nm) | (nm) | (nm) |
| Toluene | 456 | 21.9 | 464 | 19.8 | 465 | 20.7 |
| MC | 466 | 30 | 470 | 26 | 470 | 26.9 |
| THF | 456 | 23.5 | 463 | 24 | 464 | 22 |
| Acetonitrile | 464 | 31 | 469 | 26.9 | 469 | 26.9 |
| Max ΔPL | 10 | 9.1 | 6 | 7.1 | 5 | 6.2 |

The above table shows the change in emission wavelength according to the change in the polarity of the solvent. Comparative compound 1 changed the PL wavelength by 10 nm and the full width at half maximum (FWHM) by 9.1 nm depending on the polarity of the solvent, and in the case of Multifunctional Emitting Compound 3, the PL wavelength and FWHM were changed by 5 nm and 6.2 nm, respectively. In the case of Comparative compound 2, with the changes of 6 nm and 7.1 nm, respectively, there was no significant difference compared to Multifunctional Emitting Compound 3. The closer the highly polar solvent exists to the light emitting compound in the excited state, the more the wavelength shifts to a longer wavelength. Compared to Comparative compound 1, in the case of Comparative compound 2 and Multifunctional emitting compound 3, the change in wavelength in a polar solvent is smaller. This is due to the role of the first part, which is a charge stabilizing moiety by a connection portion, that spatially encloses a certain region of the emitting moiety. It can be implied that this spatial protection reduces interactions with surrounding molecules, but how much the light emission stability upon actual driving of an OLED device can be increased could be verified by manufacturing the device.

### Evaluation Example 2: Device Evaluation

The ITO surface was treated with UV ozone for 3 minutes at atmospheric pressure.

The device was processed in the following order in a 10-7 torr vacuum chamber.

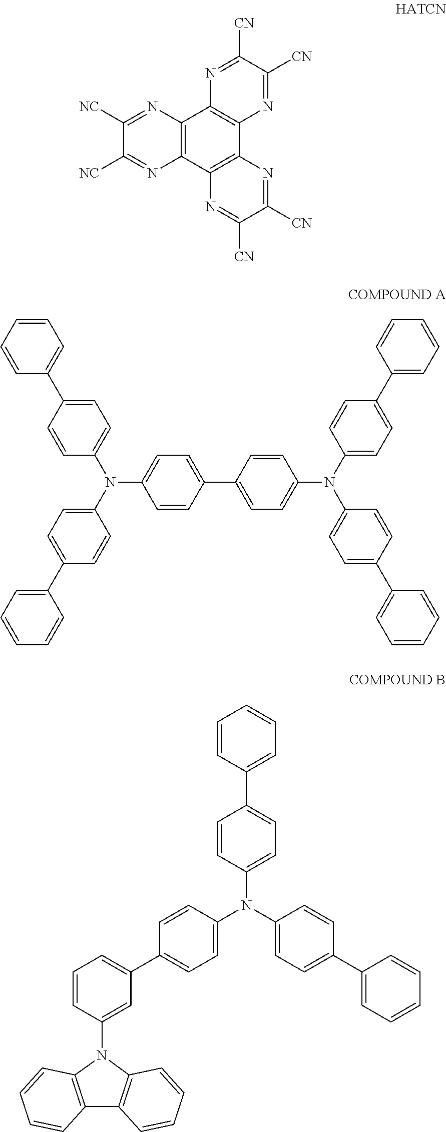 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

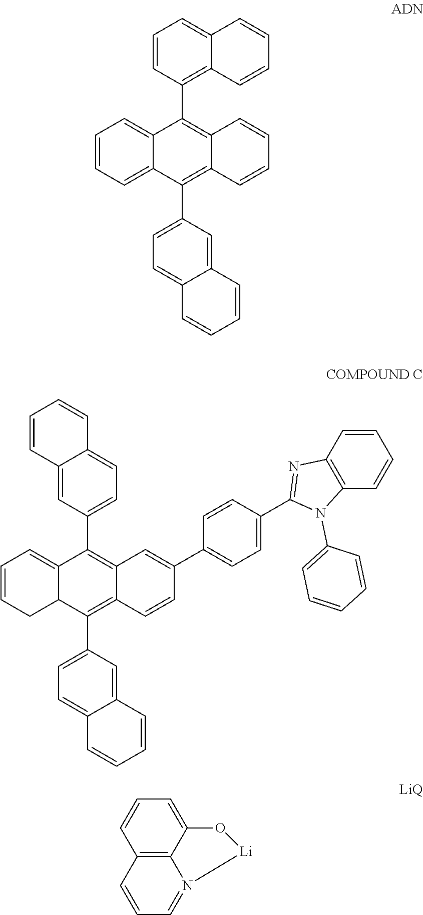

### Comparative Example 1

HATCN as a hole injection material was deposited to a thickness of 50 Å.

Compound A as a hole transport material was deposited to a thickness of 1000 Å.

For an electron blocking layer, Compound B was deposited to a thickness of 50 Å.

For an emission layer, ADN was deposited to a thickness of 250 Å while being doped with 2 mol % of Comparative compound 1.

For an electron transport layer, Compound C and LiQ were deposited to a thickness of 300 Å at a ratio of 1:1.

For an electron injection layer, LiQ was deposited to a thickness of 10 Å. For an electrode, Al was deposited to a thickness of 500 Å.

### Comparative Example 2

Organic light emitting diode (OLED) 2 was manufactured in the same manner as in OLED 1 except that the emission layer was doped with 2 mol % of Comparative compound 2 instead of Comparative compound 1.

### Example 1

OLED 3 was manufactured in the same manner as in OLED 1, except that the emission layer was doped with 4 mol % of Compound 3 instead of Comparative compound 1.

### Example 2

OLED 4 was manufactured in the same manner as in OLED 1, except that the emission layer was doped with 3 mol % of Compound 4 instead of Comparative compound 1.

In each device below, the doping % showing the maximum emitting efficiency and the time (T95) required for the brightness to decrease by 5% when a current of 20 mA/cm2 was applied to the device were measured. The results are shown in Table 2 below.

TABLE 2

| | | | Max. | | | |
|---|---|---|---|---|---|---|
| | | | efficiency | | | |
| Device | | | doping | Voltage | EQE | |
| (10 mA/cm²) | | Dopant | (mol %) | (V) | (%) | T95 |
| Compar- | OLED | Comparative | 2 | 3.7 | 6.8 | 120 |
| ative | 1 | compound 1 | | | | |
| Example | | | | | | |
| 1 | | | | | | |
| Compar- | OLED | Comparative | 2 | 3.8 | 6.9 | 140 |
| ative | 2 | compound 2 | | | | |
| Example | | | | | | |
| 2 | | | | | | |
| Example 1 | OLED | Compound 3 | 4 | 3.7 | 7.14 | 240 |
| | 3 | | | | | |
| Example 2 | OLED | Compound 4 | 3 | 3.6 | 6.27 | 220 |
| | 4 | | | | | |

As can be seen from Table above, OLED 3 and OLED 4 using Compound 3 and Compound 4 designed as the multifunctional emitting compound show stable lifetime improvement.

While the present disclosure has been described with reference to embodiments as described above, the embodiments set forth herein are not intended to limit the present disclosure, and it is obvious that various modifications can be made by those skilled in the art within the scope of the technical spirit of the present disclosure. In addition, even if not explicitly described about functioning effects according to the configurations of the present disclosure in the foregoing detailed description of embodiments, it is apparent that predictable effects of the corresponding configurations should also be acknowledged.

1. An organic light emitting diode comprising a first electrode, a second electrode and an emission layer interposed between the first electrode and the second electrode,
wherein the emission layer includes a multifunctional emitting compound,
the multifunctional emitting compound includes a charge stabilizing moiety, a connection portion and an emitting moiety,
the connection portion is formed in a linking group or in a spiro connection, connecting the charge stabilizing moiety and the emitting moiety,
the charge stabilizing moiety is an aromatic ring having 6 to 50 carbon atoms or a heteroaromatic fused ring having 5 to 50 carbon atoms,
the charge stabilizing moiety includes at least one atom having an unshared electron pair included in a HOMO or a LUMO wave function of the charge stabilizing moiety,
the charge stabilizing moiety has a polarity greater than 0.00 Debye,
a length of a longest axis of the charge stabilizing moiety is 7.5 Å or more,
a HOMO-LUMO gap energy of the charge stabilizing moiety is greater than or equal to a HOMO-LUMO gap energy of the emissive moiety;
a shortest distance between the charge stabilizing moiety and the emitting moiety by the connection portion is within 6 Å,
the emitting moiety is distinguished by a light emitting core that is a minimum conjugated structure in the emitting moiety, and a substituent part that is a remaining part thereof; or the emitting moiety is composed of the light emitting core only,
the light emitting core includes carbon and hydrogen, and further includes at least one element other than carbon and hydrogen; and said hydrogen includes hydrogen, deuterium and tritium are defined as a same element as hydrogen,
provided that, in the multifunctional emitting compound,
(i) a case where the substituent part is connected to an atom other than a carbon element in the light emitting core, and the substituent part and the light emitting core together are connected to the charge stabilizing moiety in a spiro connection, so that each of the substituent part and the light emitting core connects to a spiro atom; and
(ii) a case where the substituent part is connected to the charge stabilizing moiety in a spiro connection, and the light emitting core is connected to an atom other than a carbon element in the substituent part; are excluded.

2. The organic light emitting diode according to claim 1, wherein the emitting moiety is derived from an emitting material.

3. The organic light emitting diode according to claim 1, wherein the emitting moiety has a conjugated structure with a quantum efficiency of 50% or more in the visible light wavelength range of 400 nm to 700 nm.

4. The organic light emitting diode according to claim 1, the emitting moiety has a conjugated structure with a quantum efficiency of 0.5% or more in the near-infrared wavelength range of 700 nm to 2500 nm.

5. The organic light emitting diode according to claim 1, wherein light emitting mechanism of the emitting moiety includes fluorescence emitting light from a singlet, phosphorescence emitting light from a triplet, and thermally activated delayed fluorescence emitting light when energy is transferred from a triplet to a singlet.

6. The organic light emitting diode according to claim 1, wherein the multifunctional emitting compound is substituted with at least one deuterium.

7. The organic light emitting diode according to claim 1, wherein the linking group is a carbon atom, a silicon atom, or a Sn atom, and when the linking group is a carbon atom, a silicon atom, or a Sn atom, the linking group has a substituent(s) selected from hydrogen, alkyl having 1 to 20 carbon atoms, aryl having 6 to 20 carbon atoms, heteroaryl having 5 to 20 carbon atoms and combinations thereof, in a number according to stoichiometric ratio, or
the charge stabilizing moiety and the emitting moiety are connected in a spiro connection having carbon, silicon or Sn as a spiro atom.

8. The organic light emitting diode according to claim 1, wherein the charge stabilizing moiety and the emitting moiety do not change a HOMO energy, a LUMO energy or a band gap energy by 0.2 eV or more each other, while connecting to form the connection portion through a linking group or a spiro connection.

9. The organic light emitting diode according to claim 1, wherein the charge stabilizing moiety is (i) an aromatic fused ring having 8 to 50 carbon atoms and containing at least one atom having an unshared electron pair included in the HOMO or the LUMO wave function of the charge stabilizing moiety; or an heteroaromatic fused ring having 5 to 50 carbon atoms, or
(ii) an aromatic ring having 6 to 50 carbon atoms and having at least one substituent represented by the structure of Formula 1 or Formula 2 below; or a heteroaromatic fused ring having 5 to 50 carbon atoms and having at least one substituent represented by the structure of Formula 1 or Formula 2 below; 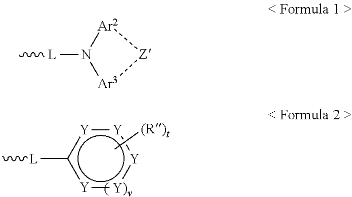
In Formula 1 or Formula 2,
L is a single bond, or a divalent group selected from the group consisting of alkylene having 1 to 20 carbon atoms, alkylsilylene having 1 to 20 carbon atoms, aryl silylene having 1 to 20 carbon atoms, alkylaryl silylene having 1 to 20 carbon atoms, oxygen, sulfur, a divalent group of aryl phosphine having 6 to 20 carbon atoms, a divalent group of aryl phosphine oxide having 6 to 20 carbon atoms, arylene having 6 to 20 carbon atoms, heteroarylene having 5 to 20 carbon atoms and combinations thereof,
Z′ does not exist, or represents a single bond, or is an atom selected from the group consisting of group IIIA, IVA, VA and VIA elements, and when Z′ is an atom, Z′ can have a substituent(s) selected from hydrogen, alkyl having 1 to 20 carbon atoms, an additional substituent substituted or unsubstituted aryl having 6 to 20 carbon atoms, an additional substituent substituted or unsubstituted heteroaryl having 5 to 20 carbon atoms and combinations thereof, in a number according to stoichiometric ratio,
Ar² and Ar³ are, each independently, an alkyl having 1 to 20 carbon atoms, an additional substituent substituted or unsubstituted aryl having 6 to 20 carbon atoms, or an additional substituent substituted or unsubstituted heteroaryl having 5 to 20 carbon atoms,
t is an integer from 0 to 5;
v is 0 or 1
R″ is, each independently, selected from the group consisting of hydrogen, deuterium, alkyl having 1 to 20 carbon atoms, an additional substituent substituted or unsubstituted aryl having 6 to 20 carbon atoms, an additional substituent substituted or unsubstituted heteroaryl having 5 to 20 carbon atoms, alkylamine having 1 to 20 carbon atoms, an additional substituent substituted or unsubstituted arylamine having 6 to 30 carbon atoms, an additional substituent substituted or unsubstituted alkylarylamines having 7 to 30 carbon atoms, halogen, CN, alkoxy having 1 to 20 carbon atoms, an additional substituent substituted or unsubstituted aryloxy having 6 to 30 carbon atoms, an additional substituent substituted or unsubstituted alkylsilyl having 1 to 20 carbon atoms, an additional substituent substituted or unsubstituted arylsilyl having 6 to 30 carbon atoms, an additional substituent substituted or unsubstituted alkylarylsilyl having 7 to 30 carbon atoms, alkylthiol having 1 to 20 carbon atoms, arylthiol having 6 to 20 carbon atoms, aryl phosphine having 1 to 20 carbon atoms, aryl phosphine oxide having 1 to 20 carbon atoms and combinations thereof, and at least two R″ can be linked to each other to form a ring,
the additional substituent is selected from the group consisting of alkyl having 1 to 20 carbon atoms, aryl having 6 to 20 carbon atoms, heteroaryl having 5 to 20 carbon atoms, alkylamine having 2 to 20 carbon atoms, alkylarylamine having 7 to 20 carbon atoms, alkylsilyl having 1 to 20 carbon atoms, arylsilyl having 6 to 20 carbon atoms, alkylarylsilyl having 7 to 30 carbon atoms, alkylthiol having 1 to 20 carbon atoms, arylthiol having 6 to 20 carbon atoms and combinations thereof,
Y is, each independently, nitrogen, oxygen, sulfur or carbon; [symbol]
indicates a connection site,
provided that L or R″ in Formula 2 includes at least one atom having an unshared electron pair included in the HOMO or the LUMO wave function of the charge stabilizing moiety, or at least one of Y is nitrogen, oxygen or sulfur.

10. The organic light emitting diode according to claim 9, wherein the substituent represented by the structure of Formula 1 or Formula 2 is represented by any of the structures of Formulae D-1 to D-38 below: 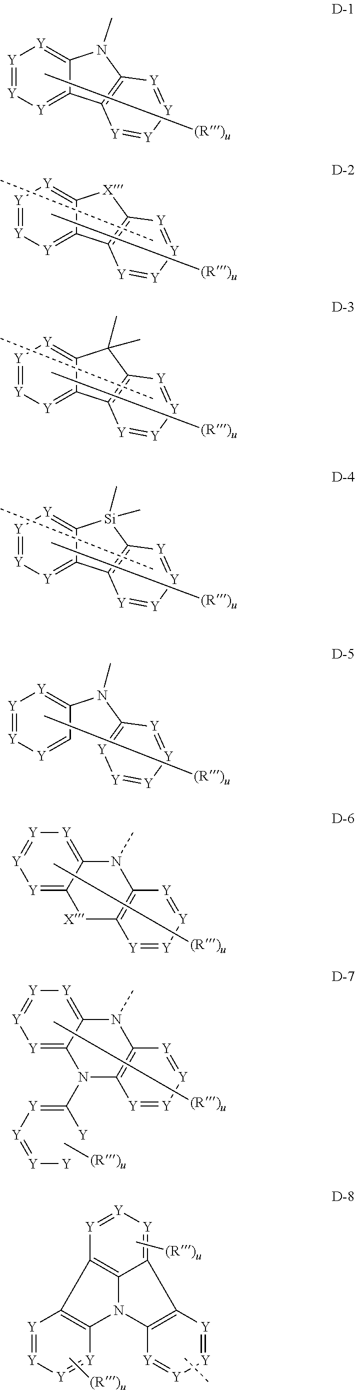 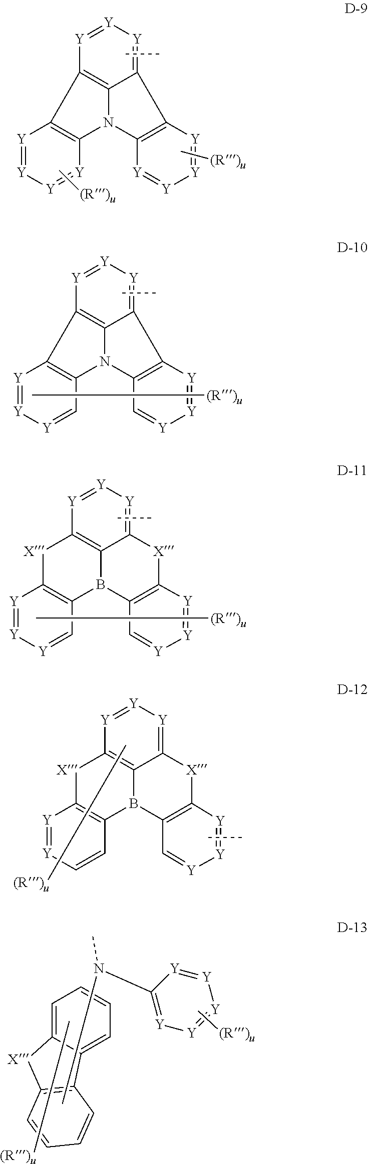 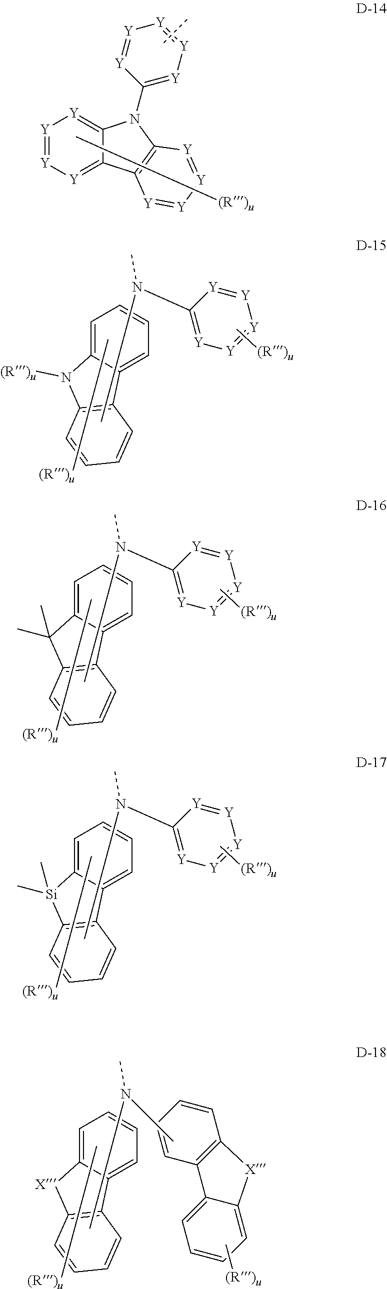 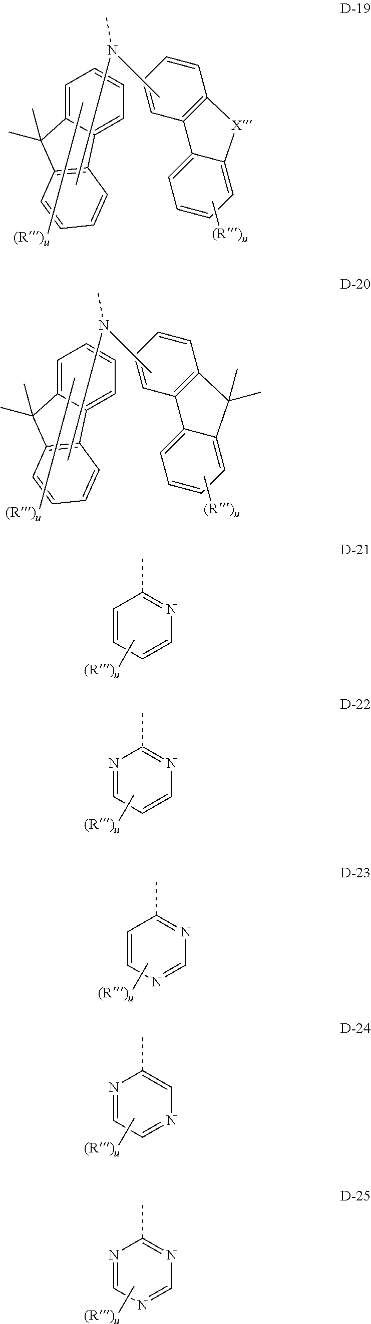 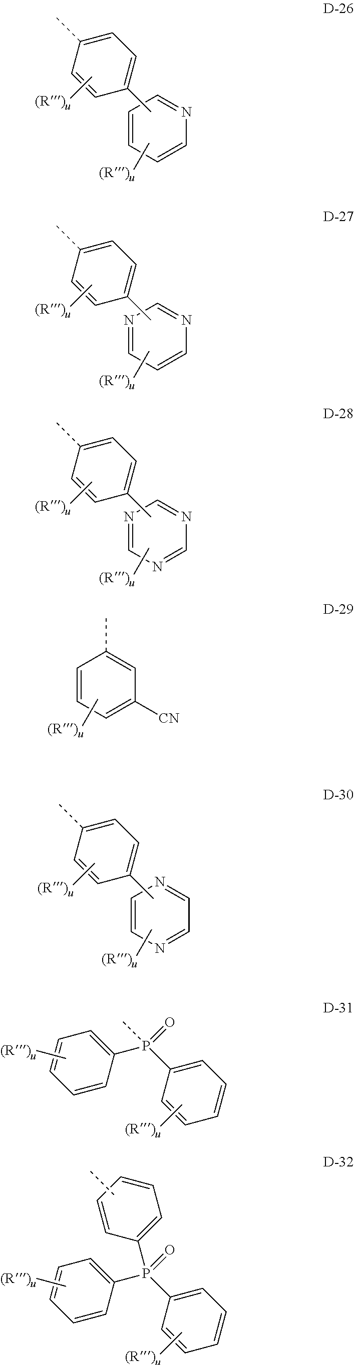 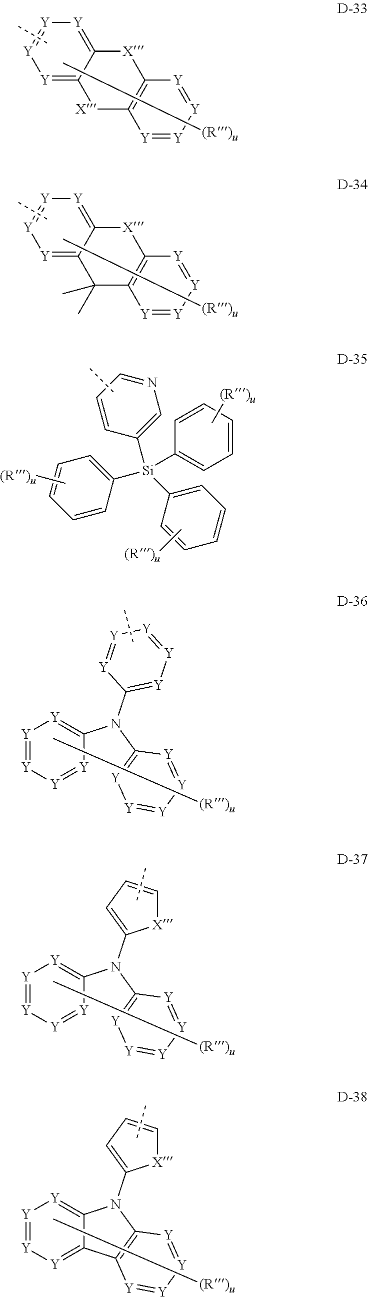
In Formulae D-1 to D-38,
Y is, each independently, carbon or nitrogen,
X″ is, each independently, oxygen, nitrogen, sulfur or selenium,
R′″ is, each independently, selected from hydrogen, deuterium, alkyl having 1 to 20 carbon atoms, aryl having 6 to 20 carbon atoms, heteroaryl having 5 to 20 carbon atoms, alkylamine having 2 to 20 carbon atoms, halogen, CN group, alkylsilyl having 4 to 20 carbon atoms, arylsilyl of 6 to 20 carbon atoms and combinations thereof,
u is, each independently, an integer from 0 to 20,
the dotted line represents a connection site,
provided that Formulae D-1 to D-38 include at least one atom having an unshared electron pair included in the HOMO or the LUMO wave function of the charge stabilizing moiety.

11. The organic light emitting diode according to claim 1, wherein the emission layer further includes a phosphorescent material containing Ir or Pt.

12. The organic light emitting diode according to claim 1, wherein the emission layer further includes a thermally activated delayed fluorescent material having a singlet and triplet energy difference of 0.3 eV or more.

13. The organic light emitting diode according to claim 1, wherein the organic light emitting diode is a tandem type organic light emitting diode including a plurality of organic light emitting units, and
at least one of the plurality of organic light emitting units includes the emission layer.
